(19) United States
(12) Patent Application Publication
(10) Pub. No.: US 2025/0149410 A1
(43) Pub. Date: May 8, 2025

(54) SEMICONDUCTOR DEVICE AND METHOD OF MANUFACTURING THE SAME

(71) Applicant: Renesas Electronics Corporation, Tokyo (JP)

(72) Inventor: Seiya ISOZAKI, Tokyo (JP)

(21) Appl. No.: 18/937,178

(22) Filed: Nov. 5, 2024

(30) Foreign Application Priority Data
Nov. 8, 2023 (JP) 2023-190650

(51) Int. Cl. H01L 23/495; H01L 21/48; H01L 21/56; H01L 23/00; H01L 23/31

(52) U.S. Cl. CPC H01L 23/49541; H01L 21/4842; H01L 21/56; H01L 23/3121; H01L 23/49582; H01L 24/48; H01L 2224/48245

(57) ABSTRACT

A method of manufacturing a semiconductor device includes: a step of forming a sealing body, and a step of irradiating a laser light to a region, which is covering a part of each of the plurality of leads, of the sealing body. Each of the plurality of leads of a lead frame LF includes a first portion having a first upper surface and a first lower surface opposite the first upper surface, and a second portion having a thickness smaller than the first portion. The second portion has a second upper surface, and a second lower surface opposite the second upper surface. In the step of irradiating the laser light, the second lower surface is exposed from the sealing body by selectively irradiating the region with the laser light.

### CROSS-REFERENCE TO RELATED APPLICATIONS

The disclosure of Japanese Patent Application No. 2023-190650 filed on Nov. 8, 2023, including the specification, drawings and abstract is incorporated herein by reference in its entirety.

### BACKGROUND

The present embodiments relate to a semiconductor device and a method of manufacturing the same.

There are disclosed techniques listed below.
[Patent Document 1] Japanese Unexamined Patent Application Publication No. 2005-191240
[Patent Document 2] Japanese Unexamined Patent Application Publication No. 2014-007287
[Patent Document t 3] Japanese Unexamined Patent Application Publication No. 2014-187308

Patent Document 1 and Patent Document 2 disclose a semiconductor device provided with a step surface (recess) on a lower surface of a lead. Also, Patent Document 3 discloses a method of irradiating a laser light, as a step of removing a dam resin embedded in a groove portion on an upper surface of a lead, in a method of manufacturing a semiconductor device.

### SUMMARY

As an aspect of a semiconductor device, there is a package where a lead, which is an external terminal, is exposed from a lower surface of a sealing body. As such a package, for example, there are QFN (Quad Flat Non-leaded package) type and DEN (Dual Flat Non-leaded package) type. When mounting the package, in which the lead is exposed from the lower surface of the sealing body, on a mounting substrate, the package is mounted by attaching a bonding material such as a solder onto an exposed surface of the lead. Also, from the perspective of improving the visibility of the solder in an inspection after mounting the package, there is a method of forming a solder fillet at a tip of the lead by forming a step portion at the tip of the lead, as shown in the above-mentioned Patent Documents 1 and 2.

However, a concern that a short-circuit may occur between two leads adjacent to each other via the solder arises, when a distance between the two leads becomes narrow due to, for example, the miniaturization of the semiconductor device. For details, for example as shown in Patent Document 2, when dicing each lead with a dicing blade, which is a rotating blade, a metal burr extending in an array direction of a plurality of leads (multiple leads) may be formed on a side surface of the sealing body, namely, on the processed surface by the dicing blade (especially, a part located between the two leads). And, when the metal burr is formed, the solder may wick along this metal burr during a mounting step of the package, thereby there is a potential causing the short-circuit between the two leads.

Therefore, in order to improve a reliability of the semiconductor device, a technology capable of preventing short-circuit between adjacent leads is needed.

Other objects and novel features will become apparent from the description of this specification and the accompanying drawings.

A method of manufacturing a semiconductor device according to one embodiment, comprising: (a) preparing a lead frame including: a die pad having a first upper surface and a first lower surface opposite the first upper surface, and a plurality of leads spaced apart from the die pad, wherein each of the plurality of leads has a second upper surface facing in the same direction as the first upper surface and a second lower surface opposite the second upper surface; (b) mounting a semiconductor chip on the first upper surface of the die pad, wherein the semiconductor chip has a plurality of electrodes; (c) electrically connecting the plurality of electrodes of the semiconductor chip with the plurality of leads via a plurality of conductive members, respectively; (d) sealing a part of the die pad, a first part of each of the plurality of leads, the plurality of conductive members and the semiconductor chip with a resin made of an insulating material in a state that a tape material is in contact with the first lower surface of the die pad and the second lower surface of each of the plurality of leads, and forming a sealing body having a third upper surface facing in the same direction as the first upper surface and a third 1 surface opposite the third upper surface; (e) removing the tape material, and irradiating a region of the sealing body with a laser light, wherein the region covers a second part of each of the plurality of leads; (f) after the (e), forming a metal film on the second lower surface of each of the plurality of leads and on the second part of each of the plurality of leads, wherein each of the plurality of leads of the lead frame prepared in the (a) includes: a first portion having the second upper surface and the second lower surface; and a second portion located further away from the die pad than the first portion and having a thickness which is smaller than a thickness of the first portion, wherein the plurality of leads of the lead frame prepared in the (a) is arranged in a first direction, wherein the second portion includes: the second upper surface; and a fourth lower surface opposite the second upper surface, wherein a length from the second upper surface to the fourth lower surface is less than a length from the second upper surface to the second lower surface, and wherein in the (e), the fourth lower surface of the second portion of each of the plurality of leads is exposed from the sealing body by selectively irradiating the region of the sealing body.

A semiconductor device according to another embodiment, comprising: a die pad having a first upper surface and a first lower surface opposite the first upper surface; a plurality of leads spaced apart from the die pad, wherein each of the plurality of leads has a second upper surface facing in the same direction as the first upper surface and a second lower surface opposite the second upper surface; a semiconductor chip mounted on the first upper surface of the die pad, wherein the semiconductor chip has a plurality of electrodes; a plurality of conductive members electrically connecting the plurality of electrodes of the semiconductor chip with the plurality of leads; and a sealing body sealing a part of the die pad, a first part of each of the plurality of leads, the plurality of conductive members and the semiconductor chip such that the first lower surface of the die pad and the second lower surface of each of the plurality of leads are exposed from the third lower surface, wherein the sealing body has a third upper surface facing in the same direction as the first upper surface and the third lower surface opposite the third upper surface, wherein each of the plurality of leads includes: a first portion having the second upper surface and the second lower surface; and a second portion located further away from the die pad than the first portion and having a thickness which is smaller than a thickness of the first portion, wherein the plurality of leads is arranged in a first direction, wherein the second portion includes: the second upper surface; and a fourth lower surface opposite the second upper surface, wherein a length from the second upper surface to the fourth lower surface is less than a length from the second upper surface to the second lower surface, wherein the plurality of leads arranged in the first direction includes two leads adjacent to each other, wherein a part of the sealing body made of an insulating material is interposed between the second portion of an one of the two leads and the second portion of an other of the two leads, and wherein, in a thickness direction of the sealing body, a length from the third upper surface to the third lower surface of the part of the sealing body is larger than a length from the third upper surface of the sealing body to the fourth lower surface of the second portion of each of the plurality of leads.

According to the above embodiment, it is possible to improve the performance of the semiconductor device.

### BRIEF DESCRIPTION OF THE DRAWINGS

FIG. 1 is an upper surface view of a semiconductor device according to one embodiment.

FIG. 2 is a lower surface view of the semiconductor device shown in FIG. 1.

FIG. 3 is a cross-sectional view along line A-A of FIG. 1.

FIG. 4 is a perspective plan view showing an internal structure of the semiconductor device without a sealing body shown in FIG. 1.

FIG. 5 is an enlarged cross-sectional view along line B-B of FIG. 2.

FIG. 6 is a cross-sectional view showing a state in which the semiconductor device shown in FIG. 3 is mounted on a mounting surface of a mounting substrate via a bonding material.

FIG. 7 is a flowchart showing an example of a manufacturing process for the semiconductor device shown in FIGS. 1 to 5.

FIG. 8 is a plan view of a lead frame prepared in the lead frame preparing step shown in FIG. 7.

FIG. 9 is an enlarged plan view at two of a plurality of devices forming portions shown in FIG. 8.

FIG. 10 is an enlarged cross-sectional view along line C-C of FIG. 9.

FIG. 11 is an enlarged cross-sectional view along line D-D of FIG. 9.

FIG. 12 is a plan view showing the sealing body formed in the sealing step shown in FIG. 7.

FIG. 13 is an enlarged cross-sectional view along line E-E of FIG. 12, showing a state in which the lead frame is placed in a cavity of a molding die.

FIG. 14 is an enlarged cross-sectional view showing a state in which a part of the sealing body, which is covering an end portion of a lead, is irradiated with a laser light in the laser irradiating step shown in FIG. 7.

FIG. 15 is an enlarged plan view showing an example of a scanning direction of a position where the laser light is irradiated in the laser irradiating step shown in FIG. 7.

FIG. 16 is an enlarged plan view showing an example after the part of the sealing body is removed by the laser irradiating step shown in FIG. 7.

FIG. 17 is an enlarged cross-sectional view along line F-F of FIG. 16.

FIG. 18 is an enlarged cross-sectional view along line G-G of FIG. 16.

FIG. 19 is an enlarged cross-sectional view showing an examined example corresponding to FIG. 14.

FIG. 20 is an enlarged plan view showing an examined example corresponding to FIG. 15.

FIG. 21 is an explanatory diagram schematically showing an example of the metal film forming step shown in FIG. 7.

FIG. 22 is an enlarged cross-sectional view showing a state in which a metal film is formed on the lead shown in FIG. 17.

FIG. 23 is an enlarged cross-sectional view showing the dicing step shown in FIG. 7.

FIG. 24 is an enlarged side surface view showing one side of the semiconductor device after completing the dicing step shown in FIG. 7.

FIG. 25 is an enlarged cross-sectional view showing a modified example corresponding to FIG. 14.

FIG. 26 is an enlarged plan view showing a modified example corresponding to FIG. 15.

FIG. 27 is an enlarged cross-sectional view showing another modified example corresponding to FIG. 14.

FIG. 28 is an enlarged plan view showing another modified example corresponding to FIG. 15.

### DETAILED DESCRIPTION

### Description of the Format and Basic Terms and Usage in this Application

In this application, the description of embodiments is divided into multiple sections as necessary for convenience, but unless expressly stated otherwise, these are not independent and separate from each other, regardless of the order of description, and parts of a single example, where one part may be a detailed part of another or a part or all of a modified example. Also, in principle, descriptions of similar parts are omitted.

Furthermore, each component in an embodiment is not essential, unless expressly stated otherwise, theoretically limited to that number, and obviously otherwise from the context.

Similarly, in the description of the embodiments and the like, regarding materials, compositions, etc., saying “X consisting of A” does not exclude elements other than A, except when it is clearly indicated that this is not the case and when it is obvious from the context. For example, regarding a component, it means “X including A as a main component.” For instance, mentioning a “silicon member” does not limit it to pure silicon but includes members containing SiGe (silicon-germanium) alloy or other multicomponent alloys with silicon as a main component, as a well as other additives. Moreover, mentioning gold plating, Cu layer, nickel plating, etc., includes not only pure materials but also members containing gold, Cu, nickel, etc., as main components, unless otherwise specified.

Furthermore, when referring to a specific numerical value or quantity, it may be greater than or less than that specific numerical value, unless expressly stated otherwise, theoretically limited to that number, and obviously not so from the context.

In the drawings of the embodiments, the same or similar parts are denoted by the same or similar symbols or reference numerals, and the description will not be repeated in principle. In addition, in the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. Furthermore, hatching or dot patterns may be applied not only in cross-sections but also to indicate that an area is not a gap or to delineate the boundaries of a region.

The technology described in the following embodiments is applicable to various package types of semiconductor devices where the lead is exposed on the underside of the sealing body. In the present embodiment, as an example, an embodiment applied to a QFN-type semiconductor device where multiple leads, which are external terminals, are exposed from the sealing body on the underside (mounting surface) is discussed.

### <Semiconductor Device>

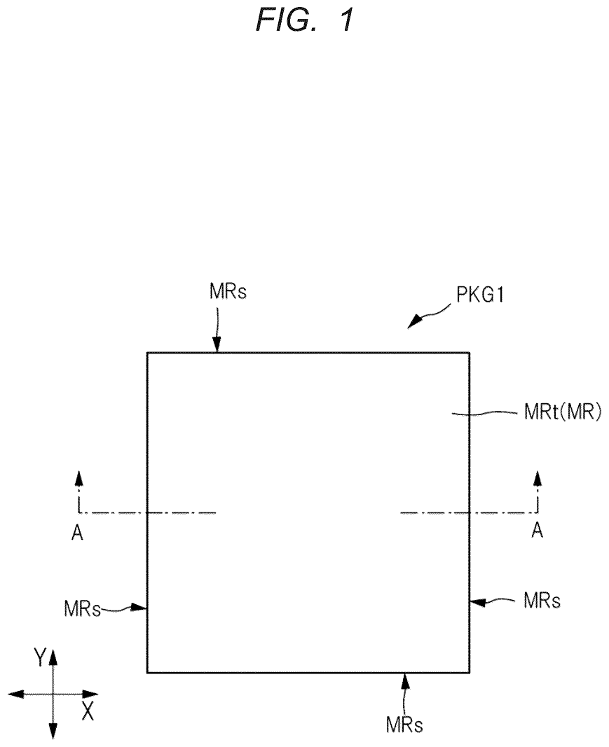

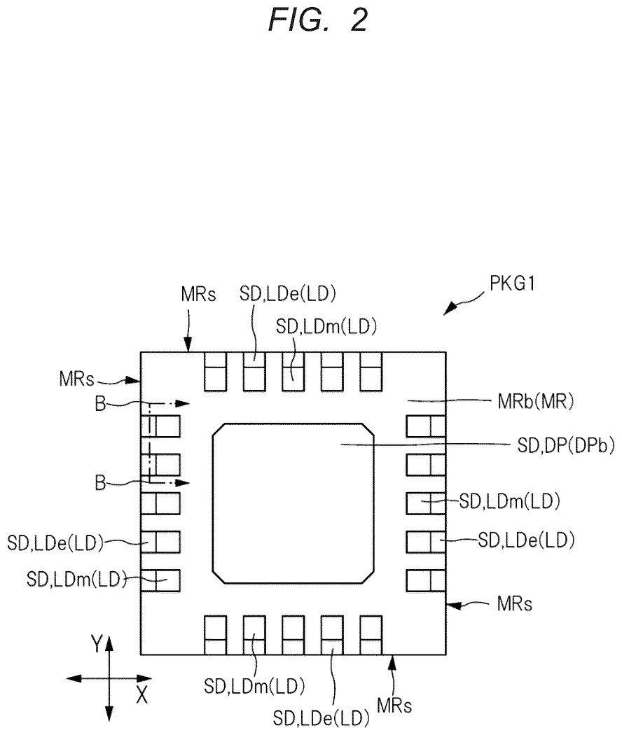

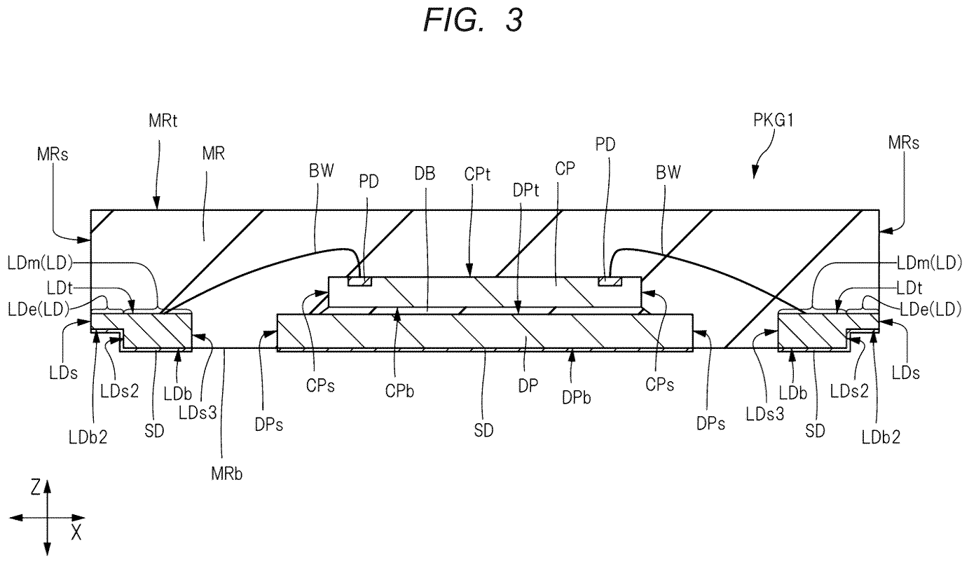

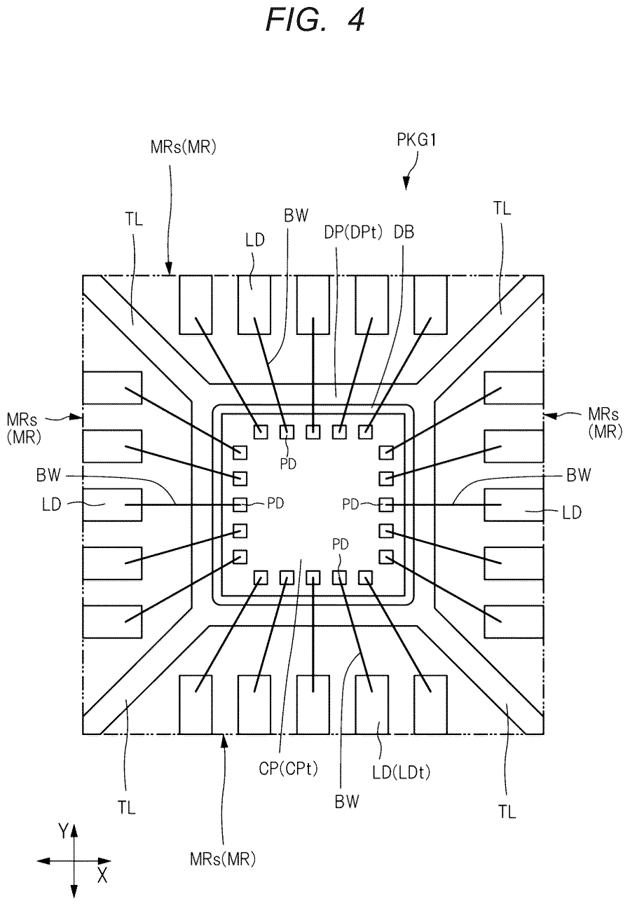

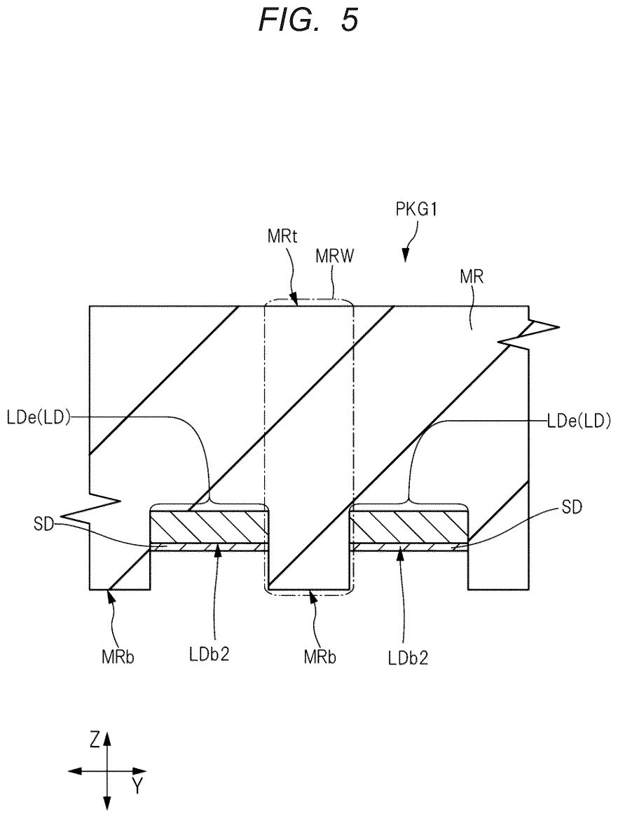

FIG. 1 is a plan view of the semiconductor device of the present embodiment, FIG. 2 is a bottom view of the semiconductor device shown in FIG. 1, and FIG. 3 is a cross-sectional view along line A-A in FIG. 1. Moreover, FIG. 4 is a perspective plan view showing the internal structure of the semiconductor device with the sealing body removed as shown in FIG. 1. FIG. 5 is an enlarged cross-sectional view along line B-B in FIG. 2.

FIGS. 1 to 5 describe either the X direction (refer to FIGS. 1, 2, 3, and 4), the Y direction (refer to FIGS. 1, 2, 4, and 5), or the Z direction (refer to FIGS. 3 and 5). The Y direction is a side that intersects with the X direction, and in the following description, the X direction and the Y direction are orthogonal to each other. The Z direction is orthogonal to both the X direction and the Y direction. In other words, the Z direction is the normal direction to the X-Y plane that includes the X direction and the Y direction. In the following description, “thickness” principally means the length in the Z direction. Also, in the following description, “plan view” principally means the view of the X-Y plane.

The semiconductor device PKG1 of the present embodiment includes a die pad (chip mounting portion, tab) DP (refer to FIGS. 3 and 4) and a semiconductor chip CP (refer to FIGS. 3 and 4) mounted on the die pad DP via a die bond material DB (refer to FIGS. 3 and 4). Furthermore, the semiconductor device PKG1 has a plurality of leads (terminals, external terminals) LD arranged around the semiconductor chip CP (die pad DP) and a plurality of wires (conductive members) BW (refer to FIGS. 3 and 4) that electrically connect the plurality of pads (electrodes, bonding pads) PD of the semiconductor chip CP (refer to FIGS. 3 and 4) and the plurality of leads LD, respectively. Moreover, the die pad DP is connected to a plurality of suspension leads TL (refer to FIG. 4). Additionally, the semiconductor device PKG1 includes a sealing body (resin body) MR that seals part of the semiconductor chip CP, the plurality of wires BW, and the plurality of leads LD.

The planar shape of the sealing body (resin body) MR shown in FIG. 1 is comprised of a quadrangle, and in the present embodiment, it is, for example, a square. The sealing body MR has an upper surface MRt, a lower surface (back surface, mounting surface) MRb located opposite to this upper surface MRt (refer to FIG. 2), and a side surface (sealing body side surface) MRs located between the upper surface MRt and the lower surface MRb. In the example shown in FIG. 3, the side surface MRs intersects with each of the upper surface MRt and the lower surface MRb. Specifically, in the example shown in FIG. 3, the side surface MRs is orthogonal to each of the upper surface MRt and the lower surface MRb.

Also, as shown in FIG. 2, in the semiconductor device PKG1, a plurality of leads LD are arranged along each side (side surface MRs) of the sealing body MR. The plurality of leads LD are each made of a metal material, and in the present embodiment, they are, for example, made of copper (Cu) or a copper alloy. Furthermore, as shown in FIG. 2, a plurality of leads LD are exposed from the sealing body MR at the lower surface MRb thereof, with a part of each lead LD (lower surface LDb) being exposed from the sealing body MR. Additionally, a metal film SD is formed on the exposed part of the lead LD from the sealing body MR, and the lower surface LDb is covered with the metal film SD. The metal film SD is, for example, a plating film formed by a plating method, made of, for example, solder material, and functions as a bonding material when bonding the lead LD to a terminal on the mounting board side, which will be described later.

The metal film SD (solder material) of the present embodiment is made of so-called lead-free solder, which substantially does not contain lead (Pb), and is, for example, made of only tin (Sn), tin-bismuth (Sn—Bi), or tin-copper-silver (Sn—Cu—Ag). Here, lead-free solder means solder containing less than 0.1 wt % of lead (Pb), and this content is defined as the standard of the RoHS (Restriction of Hazardous Substances) directive. Hereinafter, in the present embodiment, unless specifically stated otherwise, the term “solder material” or “solder component” refers to lead-free solder.

As shown in FIG. 2, each of the plurality of leads LD has a part (portion, wire bonding portion) LDm and a part (portion, end portion, step portion) LDe, which is located further away from the die pad DP than the part LDm.

As shown in FIG. 3, the part LDm includes an upper surface LDt and a lower surface LDb, which is opposite to the upper surface LDt. The upper surface LDt of the part LDm is connected with a wire BW. The part LDe has an upper surface LDt and a lower surface (step surface) LDb2, which is opposite to the upper surface LDt. The length from the upper surface LDt to the lower surface LDb2 is less than the length from the upper surface LDt to the lower surface LDb. The thickness of the part LDe is smaller than the thickness of the part LDm.

Although details will be described later, at the peripheral part of the lower surface (mounting surface) of the semiconductor device PKG1, the provision of the part LDe, which is a step part, for each of the plurality of leads LD improves the visibility during inspection after mounting. Also, as shown in FIG. 5, in the case of the present embodiment, a portion (part) MRW of the sealing body MR, made of an insulating material, is interposed between the portions LDe of adjacent leads LD. Specifically, the plurality of leads LD arranged in the Y direction, as shown in FIG. 4, includes two leads LD that are adjacent to each other. Among the two adjacent leads LD shown in FIG. 5, a portion MRW of the sealing body MR made of the insulating material is interposed between the part LDe of one and the part LDe of the other. In the thickness direction (Z direction) of the sealing body MR, the length from the upper surface MRt to the lower surface MRb of the portion (part) MRW of the sealing body MR is larger than the length from the upper surface MRt of the sealing body MR to the lower surface LDb2 of the part (portion) LDe of each of the plurality of leads LD, as shown in FIG. 5. Taking the plane including the lower surface LDb2 as a reference plane, the portion MRW protrudes from the reference plane such that the length from the upper surface MRt to the lower surface MRb of the portion MRW is longer than the length from the upper surface MRt of the sealing body MR to the lower surface LDb2 of the part LDe of the lead LD.

In the case where the portion MRW is interposed between each part LDe of two adjacent leads LD, the direction of solder wetting spread that is joined to the lead LD is regulated by the portion MRW (specifically, the portion protruding from the reference surface including the lower surface LDb2 of the portion MRW). As a result, compared to when the portion MRW is absent, even if the space between adjacent leads LD is reduced, short-circuiting between the leads can be prevented.

The part LDm includes a side surface (lead side surface) LDs facing the side surface DPs of the die pad DP, and a side surface (lead side surface) LDs2 located opposite the side surface (lead side surface) LDs3. The side surface LDs is continuous with the upper surface LDt and the lower surface LDb. The side surface LDs2 is continuous with the lower surface LDb2 and the lower surface LDb.

The part LDe has a side surface (lead side surface) LDs that is located at the farthest position from the part LDm. The side surface LDs is the farthest from the die pad DP, among the plurality of lead side surfaces of each of the plurality of leads LD. The side surface LDs is continuous with the upper surface LDt and the lower surface LDb2. Although details will be described later, the semiconductor device PKG1 is manufactured by a so-called MAP type manufacturing method. In the MAP type semiconductor device, during the described singulation step, the lead LD is cut together with the sealing body MR. Therefore, as shown in FIG. 3, the side surface LDs is positioned on the extension of the side surface MRs of the sealing body MR. In other words, the side surface MRs and the side surface LDs are arranged within the same plane with each other. Further rephrased, in the Z direction, the position of the side surface LDs and the position of the side surface MRs coincide with each other. Such a state is referred to as “the side surface LDs and the side surface MRs are flush.”

As shown in FIG. 2, the lower surface DPb of the die pad (chip mounting portion, tab) DP is exposed from the sealing body MR at the lower surface MRb of the sealing body MR. That is, the semiconductor device PKG1 is a die pad exposed type (tab exposed type) semiconductor device. Moreover, the die pad DP is made of a metal material with higher thermal conductivity than the sealing body MR, and in the present embodiment, it is made of, for example, copper (Cu) or a copper alloy. Thus, the die pad exposed type semiconductor device, by exposing a metal member (die pad DP) such as copper (Cu) with higher thermal conductivity than the sealing body MR, can improve the heat dissipation of the package compared to semiconductor devices where the die pad DP is not exposed. Also, in the examples shown in FIGS. 2 and 3, a metal film SD, which functions as a bonding material during mounting, is formed on the lower surface DPb of the die pad DP, and covering the lower surface of the above-mentioned substrate. The metal film SD is a plating film (solder film) formed by plating, for example, as mentioned above.

As shown in FIGS. 2 and 4, the upper surface (chip mounting surface) DPt of the die pad DP has a planar shape consisting of a quadrilateral. In the present embodiment, it is, for example, a square. Also, in the example shown in FIG. 4, the outer size (planar size of the back surface CPb) of the semiconductor chip CP is smaller than the outer size (planar size) of the die pad DP. Thus, by mounting the semiconductor chip CP on the die pad DP having a larger area than its outer size and exposing the lower surface DPb of the die pad DP from the sealing body MR, the heat dissipation can be improved.

Furthermore, as shown in FIGS. 3 and 4, a semiconductor chip CP is mounted on the die pad DP. The semiconductor chip CP is mounted in the center (including the central region) of the die pad DP. As shown in FIG. 3, the semiconductor chip CP is mounted on the die pad DP through a die bond material (adhesive) DB, with the back surface CPb of the semiconductor chip CP facing the upper surface DPt of the die pad DP. In other words, the semiconductor chip CP is mounted by a so-called face-up mounting method, which involves facing the opposite surface (back surface CPb) of the surface (main surface) CPt, where multiple pads PD are formed, towards the chip mounting surface (upper surface DPt). In the present embodiment, the die bond material DB used is an adhesive for die bonding the semiconductor chip CP, which includes metal particles made of, for example, silver (Ag) in an epoxy-based thermosetting resin.

As shown in FIG. 4, the planar shape of the semiconductor chip CP mounted on the die pad DP is rectangular. In the present embodiment, it is, for example, square. Also, as shown in FIG. 3, the semiconductor chip CP has a surface (main surface, upper surface) CPt, a back surface (main surface, lower surface) CPb located opposite the surface CPt, and a side surface CPs located between the surface CPt and the back surface CPb.

As shown in FIGS. 3 and 4, multiple pads (bonding pads) PD are formed on the surface CPt of the semiconductor chip CP, and in the present embodiment, multiple pads PD are formed along each edge of the surface CPt. Although not shown, multiple semiconductor elements (circuit elements) are formed in the main surface (specifically, in the semiconductor element formation area provided on the upper surface of the substrate (semiconductor substrate) of the semiconductor chip CP). Furthermore, the multiple pads PD are electrically connected to these semiconductor elements through wiring (not shown) formed in the wiring layer located inside (specifically, between the surface CPt and the unshown semiconductor element formation area) of the semiconductor chip CP.

The semiconductor chip CP (specifically, the substrate of the semiconductor chip CP) is made of, for example, silicon (Si). Also, an insulating film covering the substrate and wiring of the semiconductor chip CP is formed on the surface CPt, and the surface of each of the multiple pad's PD is exposed in the opening formed in this insulating film. Furthermore, the pad PD is made of metal, and in the present embodiment, it is made of, for example, aluminum (Al) or an alloy layer primarily composed of aluminum (Al).

Furthermore, as shown in FIG. 4, multiple leads LD made of, for example, the same copper (Cu) as the die pad DP is arranged around the semiconductor chip CP (in other words, around the die pad DP). Each of the multiple leads LD is arranged to be spaced apart from the die pad DP. Also, each of the multiple leads LD is arranged to be spaced apart from each other.

A plurality of pads (bonding pads) PD formed on the surface CPt of the semiconductor chip CP is electrically connected with a plurality of leads LD via a plurality of wires (conductive members) BW, respectively. The wire BW, for example, is made of gold (Au) or copper (Cu), with a part of the wire BW (for example, one end) being bonded to the pad PD, and another part (for example, the other end) being bonded to a bonding area on the upper surface LDt of the lead LD. Although not shown in the figures, a plating film is formed on the surface of the bonding area of the lead LD. The plating film is made of, for example, silver (Ag) or gold (Au). By forming a plating film made of silver (Ag) or gold (Au) on the surface of the bonding area (wire bonding area) of the lead LD (inner lead part), it is possible to improve the bonding strength with the wire BW made of gold (Au).

As shown in FIG. 4, a plurality of suspension leads TL are connected (linked) to the die pad DP. Each of the plurality of suspension leads TL is connected at one end to a corner (corner) of the die pad DP, which forms a quadrangle in plain view. Also, each of the plurality of suspension leads TL extends towards a corner of the sealing body MR at the other end. By extending the suspension leads TL towards the corners of the sealing body MR, it is possible to arrange them without hindering the arrangement of a plurality of leads LD arranged along each side (each main side) of the sealing body MR, thereby increasing the number of leads LD, that is, the number of terminals of the semiconductor device PKG1. In addition, the suspension leads TL are subjected to half-etching processing from the lower surface side, and the lower surface side is sealed by the sealing body MR. This allows the suspension leads TL and the sealing body MR to be firmly fixed, preventing the suspension leads TL from falling out of the sealing body MR.

<State after Mounting Semiconductor Device>

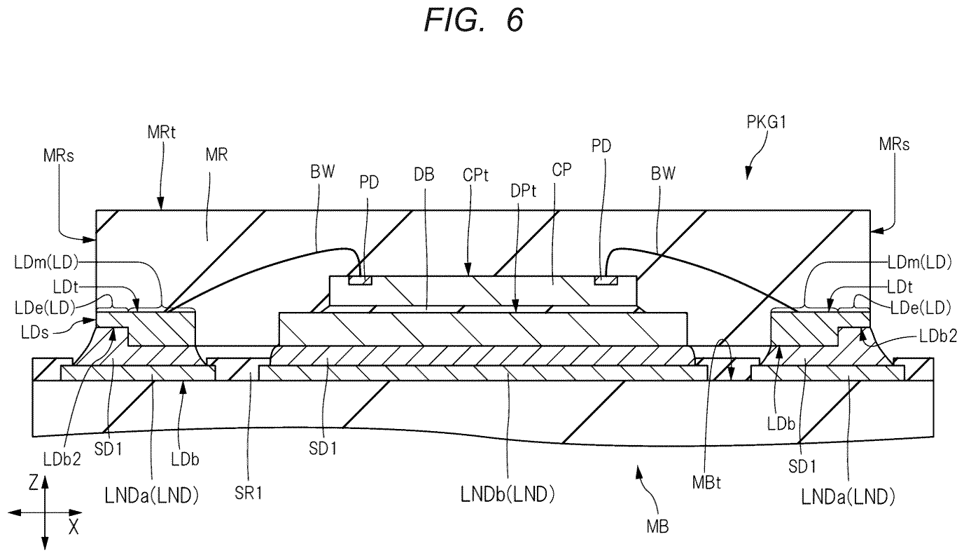

Next, the state in which the semiconductor device described using FIGS. 1 to 4 is mounted on a mounting board will be described. FIG. 6 is a cross-sectional view showing the state in which the semiconductor device shown in FIG. 3 is mounted on the mounting surface of the mounting board through a bonding material. The mounting board structure shown in FIG. 6 includes a mounting board MB and a semiconductor device PKG1 mounted on the mounting board MB.

The mounting board (motherboard, wiring board) MB has an upper surface (mounting surface) MBt, which is an electronic component mounting surface, and the semiconductor device PKG1 described using FIGS. 1 to 4 is mounted on the upper surface MBt. On the upper surface MBt, a plurality of lands (terminals) LND, which are terminals on the side of the mounting board, are arranged. In the example shown in FIG. 6, the mounting board MB includes a plurality of lands (lead connection terminals) LNDa, and lands (die pad connection terminals) LNDb. The upper surface MBt is covered with an insulating film (solder resist film) SR1, but the insulating film SR1 has openings formed at positions overlapping with the plurality of lands LND, and at these openings, the plurality of lands LND are exposed from the insulating film SR1.

A bonding material SD1 is arranged (applied) on each of the plurality of lands LND. The bonding material SD1 is made of, for example, solder material, and is a metal member integrated with the metal film SD shown in FIG. 3.

In the step of electrically connecting the semiconductor device PKG1 and the mounting substrate MB via a solder material SD1 made of solder, for example, a reflow process is performed after heating to above the melting point of the solder and then cooling. At this time, the metal film SD (refer to FIG. 3) integrates with the solder material SD1. By this reflow process, the solder material SD1 is bonded to the lead LD and the land LNDa (or to the die pad DP and the land LNDb), and the semiconductor device PKG1 and the mounting substrate MB are electrically connected via the solder material SD1.

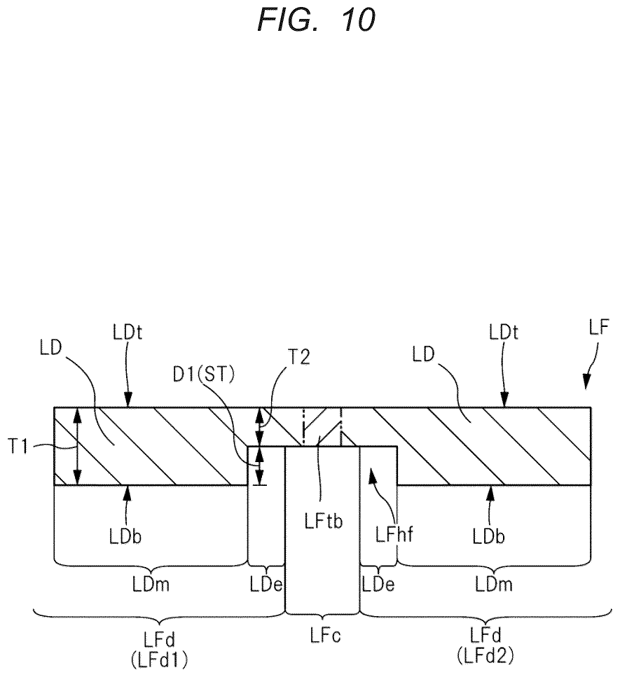

At this time, when the solder material SD1 is heated, the solder material SD1 wets and spreads over the entire exposed surface of the land LND. Furthermore, the solder material SD1 wets and spreads over the entire lower surface DPb, which is the exposed surface of the die pad DP. In addition, the solder material SD1 wets and spreads on the exposed surface of the lead LD, including the lower surface LDb and the step portion between the lower surface LDb and the lower surface LDb2, which is shown in FIG. 10 as the step portion ST. On the other hand, as shown in FIG. 3, since the metal film SD is not formed on the side surface LDs, it is difficult for the solder material SD1 shown in FIG. 6 to wet and spread on the side surface LDs.

Next, after the semiconductor device PKG1 is mounted on the mounting substrate MB, the mounting state of the mounted semiconductor device PKG1 is inspected visually. In this step, the connection part between the semiconductor device PKG1 and the mounting substrate MB, that is, the bonding state by the solder material SD1, is inspected. In this step, for example, the inspection is performed visually from the upper surface side of the semiconductor device PKG1 (the upper surface MRt side of the sealing body MR shown in FIG. 6) or using image processing.

In the case of the present embodiment, each of the multiple leads LD is provided with a step portion (part LDe) at its periphery. In this case, the distance (height difference) from the lower surface LDb2 of part LDe to the land LNDa is greater than the distance (height difference) from the lower surface LDb of part LDm to the land LNDa. Therefore, a solder fillet, which is easy to visually inspect from above (in other words, easy to perform pass/fail judgment), is formed at the periphery of the solder material SD1.

Thus, in the case of the present embodiment, since each of the multiple leads LD has the part LDe at the periphery of the semiconductor device PKG1, it is possible to easily confirm the electrical connection state between the multiple leads LD and the multiple lands LNDa during the appearance inspection after mounting on the mounting substrate MB.

Further details regarding the structure of part LDe of the lead LD will be described later.

### <Method of Manufacturing Semiconductor Device>

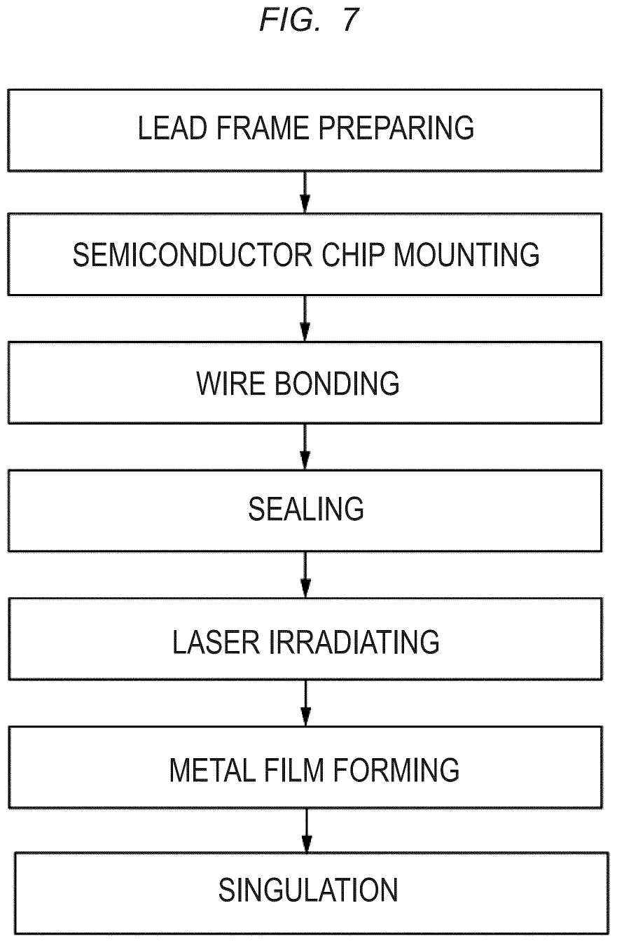

Next, the method of manufacturing the semiconductor device shown in FIGS. 1 to 4 will be explained. FIG. 7 is a flowchart showing an example of the manufacturing process of the semiconductor device shown in FIGS. 1 to 5. In the example shown in FIG. 7, the manufacturing method of the semiconductor device of the present embodiment includes a lead frame preparing step, a semiconductor chip mounting step, a wire bonding step, a sealing step, a laser irradiating step, a metal film forming step (plating step), and a singulation step.

### <Lead Frame Preparing Step>

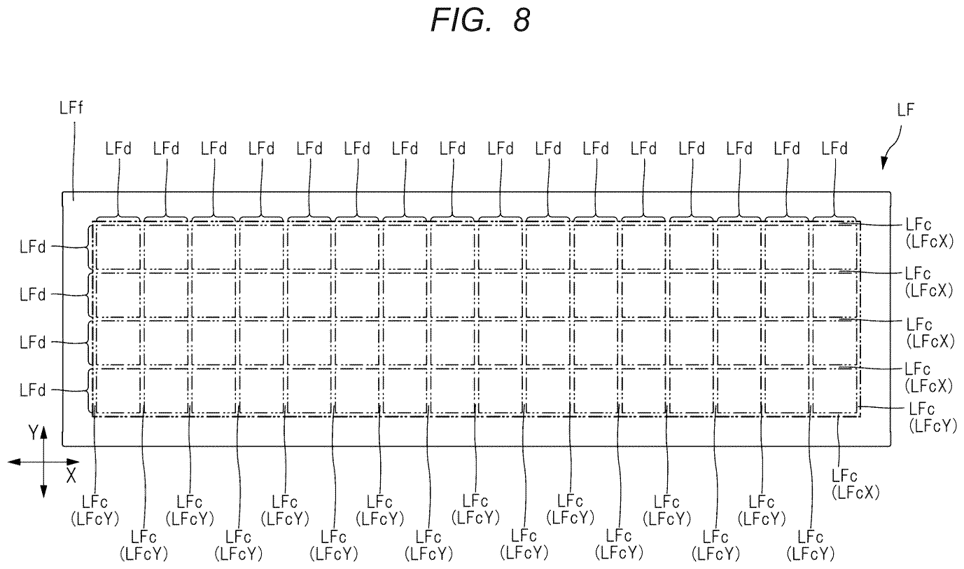

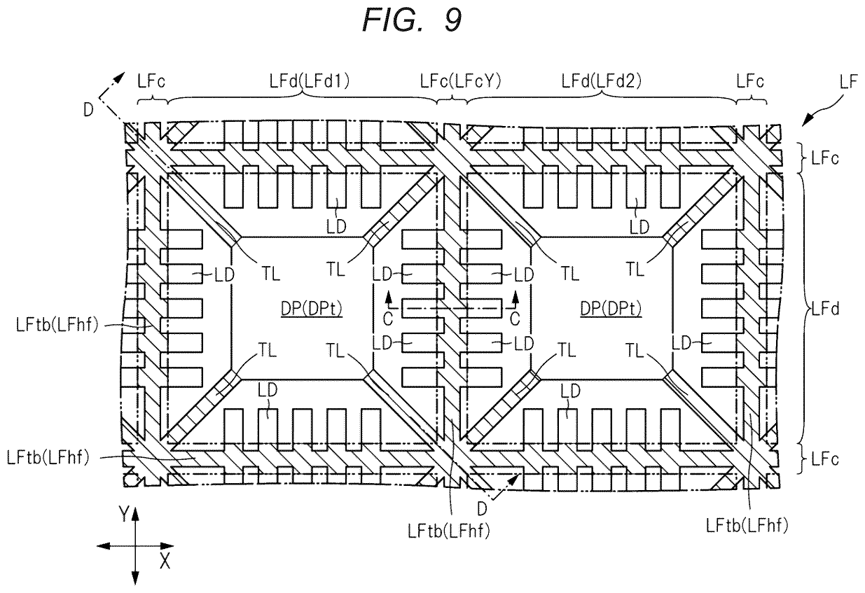

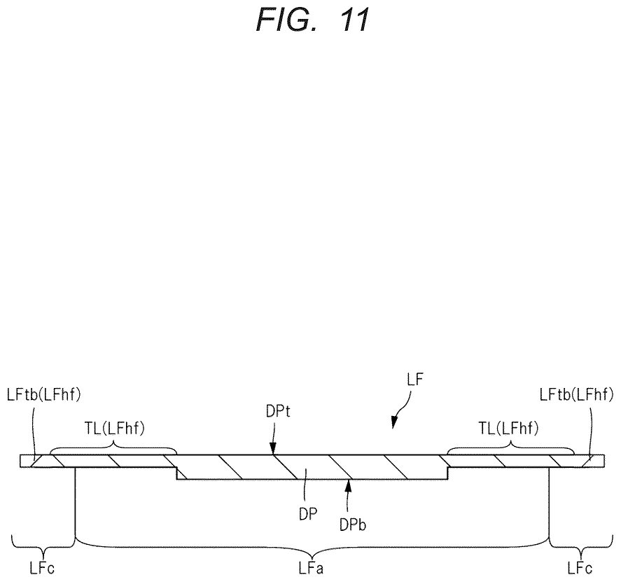

First, in the lead frame preparing step shown in FIG. 7, a lead frame LF shown in FIGS. 8 to 9 is prepared. FIG. 8 is a plan view of the lead frame prepared in the lead frame preparing step shown in FIG. 7. FIG. 9 is an enlarged plan view of two of the multiple device formation parts shown in FIG. 8. FIG. 10 is an enlarged cross-sectional view along line C-C in FIG. 9. FIG. 11 is an enlarged cross-sectional view taken along line D-D of FIG. 9. Although FIG. 9 is a plan view, the range of the portion where the plate thickness is reduced is explicitly indicated by hatching the thin-walled portion LFhf.

As shown in FIG. 8, the lead frame LF prepared in this process includes a plurality of device forming sections (device forming portions) LFd connected to the frame section (frame portion) LFf. Furthermore, the lead frame LF includes a dicing section (dicing portion) LFc provided between the device forming sections LFd that are adjacent to each other among the plurality of device forming sections LFd.

The lead frame LF is made of, for example, copper (Cu) or a copper alloy. Each of the plurality of device forming sections LFd is connected to the frame section LFf. The frame section LFf serves as a support section that supports each member formed within the device forming section LFd until the individualization process shown in FIG. 7.

Each of the plurality of device forming sections LFd corresponds to one semiconductor device PKG1 as shown in FIG. 1. Each of the plurality of device forming sections LFd has a die pad DP and a plurality of leads LD that are spaced apart from the die pad DP. The lead frame LF is a so-called multi-unit substrate where the plurality of device forming sections LFd are arranged in a matrix. Thus, by using the lead frame LF equipped with the plurality of device forming sections LFd, it is possible to manufacture a plurality of semiconductor devices PKG1 (refer to FIG. 1) in bulk, thereby improving manufacturing efficiency. Moreover, the dicing section LFc is a planned cutting area to be cut by a dicing blade in the individualization process shown in FIG. 7. The plurality of dicing sections LFc includes multiple dicing sections LFcX extending in the X direction and multiple dicing sections LFcY extending in the Y direction.

As shown in FIG. 9, the dicing portion LFc is formed so as to surround the device forming section LFd. Furthermore, tie bars LFtb are arranged in the dicing portion LFc so as to surround the device forming section LFd. The tie bars LFtb are integrally formed with the plurality of leads LD and the frame section (frame body) LFf shown in FIG. 8.

In the case of distinguishing between the two devices forming sections LFd shown in FIG. 9, they can be distinguished as device forming section LFd1 and device forming section LFd2. For example, the embodiment shown in FIG. 9 can be expressed as follows: That is, the lead frame LF has the device forming section LFd1, the device forming section LFd2 located next to the device forming section LFd1 in the X direction, and the dicing section LFcY that is arranged between the device forming section LFd1 and the device forming section LFd2 and extends in the Y direction.

Moreover, in part of the lead frame LF, it is pre-processed so that the thickness of the plate becomes thinner. In other words, as shown with hatching in FIG. 9, the lead frame LF has a thin section (half-etching section) LFhf, which is thinner than other areas. In the examples shown from FIG. 9 to FIG. 11, the thin section LFhf is formed by a half-etching processing, which etches up to halfway through from the bottom surface LDb side of the lead LD in the thickness direction. Specifically, the thickness of the tie bar LFtb and a part of the lead LD adjacent to the tie bar LFtb (the part LDe shown in FIG. 10) is thinner than the thickness of other parts of the lead LD (the part LDm shown in FIG. 10).

As shown in FIG. 10, a tie bar LFtb and a part of a lead LD located within a dicing section LFc between adjacent device forming sections LFd are formed as a thin section LFhf. In other words, a part of the tie bar LFtb and the lead LD has a portion of the bottom side of the lead frame removed, making it thinner than other parts of the lead LD. Further, the tie bar LFtb and a part of the lead LD, designated as LDe, have a portion of the metal removed in advance, forming a step section ST.

As a modified example of the present embodiment, in the lead frame preparation process, the step section is not formed, and a method involves removing metal from the lead LD during the laser irradiating step shown in FIG. 7 to form the part LDe shown in FIGS. 3 and 5.

In the case of the present embodiment, the step section ST (in other words, the part LDe of the lead LD) is pre-formed in the lead frame preparation process shown in FIG. 10. Thus, when the step section ST is pre-formed, it is only necessary to remove the resin within the step section ST during the laser irradiating step shown in FIG. 7. Therefore, the irradiation time of the laser light can be shortened during the laser irradiating step.

Moreover, in the lead frame preparation process, if the dicing section LFc is pre-formed as a thin section LFhf, the amount of metal to be cut during the singulation step shown in FIG. 7 can be reduced. Thus, it is possible to reduce metal burrs generated during the cutting process and improve the reliability of the semiconductor device.

Furthermore, as shown in FIG. 11, the suspension lead TL is formed as a thin section LFhf. By making the suspension lead TL a thin section LFhf, the underside of the suspension lead TL can be sealed during the sealing process shown in FIG. 7, thereby preventing the die pad DP from falling out of the sealing body.

As explained using FIG. 6, to form a solder fillet that is easily visible during external inspection, it is preferable for the depth D1 of the step section ST shown in FIG. 10 to be deeper. For example, in the case shown in FIG. 10, the depth D1 of the step section ST is half of the thickness T1 of the part LDm of the lead LD. In other words, the thickness T2 of the part LDe of the lead LD is half of the thickness T1 of the part LDm. The thickness T2 of the part LDe of the lead LD can be made thinner within a range that allows each of the multiple leads LD to retain the required strength from the lead preparation process to the singulation step. Therefore, it is preferable for the depth D1 of the step section ST to be at least half of the thickness T1 of the part LDm of the lead LD. Moreover, the thickness T2 of the part LDe of the lead LD is preferably half or less of the thickness T1 of the part LDm. For example, the thickness T1 of the part LDm of the lead LD is between 150 μm and 200 μm. On the other hand, the depth D1 of the step section ST is preferably about 75 μm to 100 μm.

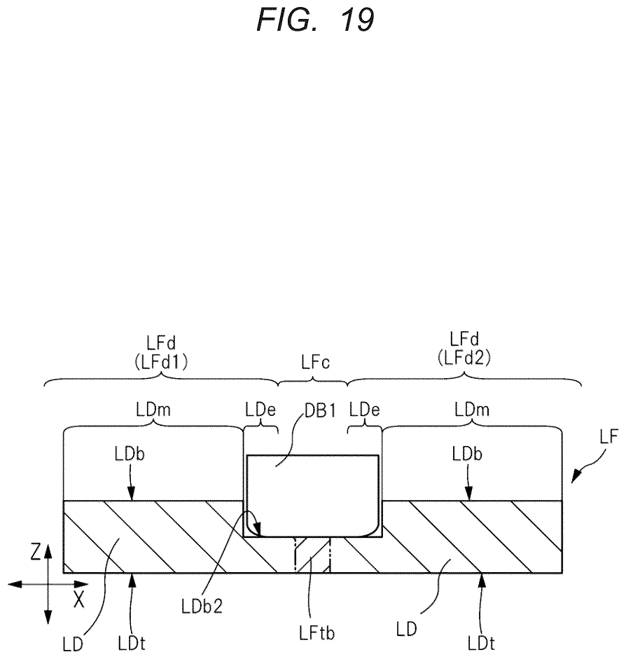

Note that, in the present embodiment, although the method of forming the part LDe by an etching process has been described, there are various modified examples of the method for forming the part LDe (the method of removing a part of the metal member constituting the lead frame). For example, a method of forming the part LDe by so-called half dicing using a cutting tool such as the dicing blade DB1 shown in FIG. 19 as an examined example can be exemplified.

When forming the part LDe by half dicing, metal burrs may occur around the part LDe. However, even if metal burrs are generated in the lead frame preparation process, the metal burrs are sealed in the sealing process shown in FIG. 7. Therefore, as a method of forming the part LDe in the lead frame preparation process, various modified examples can be applied in addition to the etching process.

### <Semiconductor Chip Mounting Step>

In the semiconductor chip mounting process shown in FIG. 7, as shown in FIGS. 3 and 4, the semiconductor chip CP is mounted on the die pad DP via a die bond material DB. Although this process is explained using FIGS. 3 and 4, the semiconductor chip CP is mounted on the die pad DP of each of the multiple devices forming portions LFd shown in FIG. 9.

In this process, for example, the semiconductor chip CP is mounted in a so-called face-up mounting method, where the back surface CPb of the semiconductor chip CP (the surface opposite to the surface CPt where multiple pads PD are formed) faces the upper surface DPt of the die pad DP. Furthermore, as shown in FIG. 4, the semiconductor chip CP is mounted in the center of the die pad DP so that each side of the surface CPt is arranged along each side of the die pad DP.

In this process, for example, the semiconductor chip CP is mounted via a die bond material DB, which is an epoxy-based thermosetting resin, but the die bond material DB is a paste material that is fluid before curing (thermosetting). In the case of using a paste material as the die bond material DB, first, the die bond material DB is applied to the die pad DP, and then, the back surface CPb of the semiconductor chip CP is adhered to the upper surface DPt of the die pad DP. Then, after the adhesion, by curing the die bond material DB (for example, by applying heat treatment), as shown in i FIG. 3, the semiconductor chip CP is fixed on the die pad DP via the die bond material DB.

Furthermore, in this process, the die bond material DB and the semiconductor chip CP are respectively placed on the die pad DP provided in each of the multiple devices forming portions LFd. And the semiconductor chip CP is mounted on each device forming section LFd.

In the present embodiment, although an embodiment using a paste material made of a thermosetting resin as the die bond material DB has been described, various modified examples can be applied. For example, solder material may be used as the die bond material DB.

### <Wire Bonding Step>

Next, in the wire bonding step shown in FIG. 7, as shown in FIGS. 3 and 4, multiple pads (electrodes) PD of the semiconductor chip CP and multiple leads LD are electrically connected to each other via multiple wires (conductive members) BW.

In this process, for example, a lead frame LF, on which semiconductor chips CP (refer to FIG. 3) are mounted on the die pads DP of the multiple devices forming sections LFd shown in FIG. 9, is placed on a heat stage (lead frame heating stage) not shown in the figures. Then, as shown in FIGS. 3 and 4, the pad PD of the semiconductor chip CP and the lead LD are electrically connected with each other via a wire BW. In the present embodiment, for example, the wire BW is supplied through a capillary not shown in the figures, and the wire BW is connected by a so-called nail head bonding method, which uses a combination of ultrasonics and thermocompression bonding. It should be noted that various modified examples can be applied to the wire bonding method.

A part of the lead LD (the bonding area located at the tip of the inner lead section) is formed with a plating film made of, for example, silver (Ag) or gold (Au), and a part of the wire BW is electrically connected with the lead LD via this plating film. Moreover, the wire BW is made of metal, and in the present embodiment, for example, it is made of gold (Au) or copper (Cu).

Furthermore, in the present embodiment, after connecting a part (end) of the wire with the pad PD of the semiconductor chip CP, the other part of the wire BW is connected with the bonding area (a part of the upper surface of the lead LD) on the lead LD by a so-called forward bonding method. Also, the wire bonding area is located opposite to the lower surface LDb shown in FIG. 3. That is, since the wire BW is bonded to a thick part of the lead LD, LDm, sufficient load can be applied when bonding the wire BW to the lead LD, thereby improving the bonding strength.

Moreover, in this process, the wire BW is bonded to the multiple leads LD provided in each of the multiple devices forming sections LFd shown in FIG. 9. As a result, in each device forming section LFd, the semiconductor chip CP and the multiple leads LD are electrically connected with each other via the multiple wires BW.

### <Sealing Step>

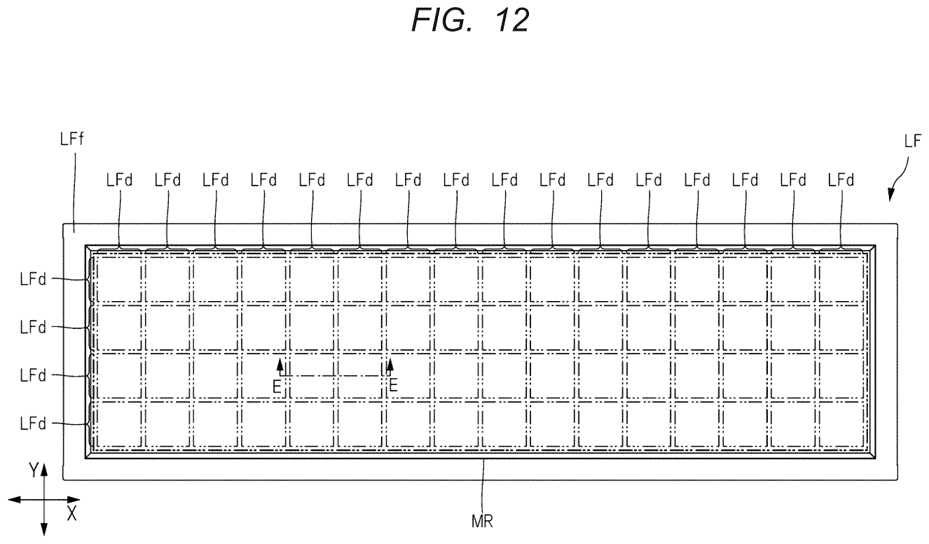

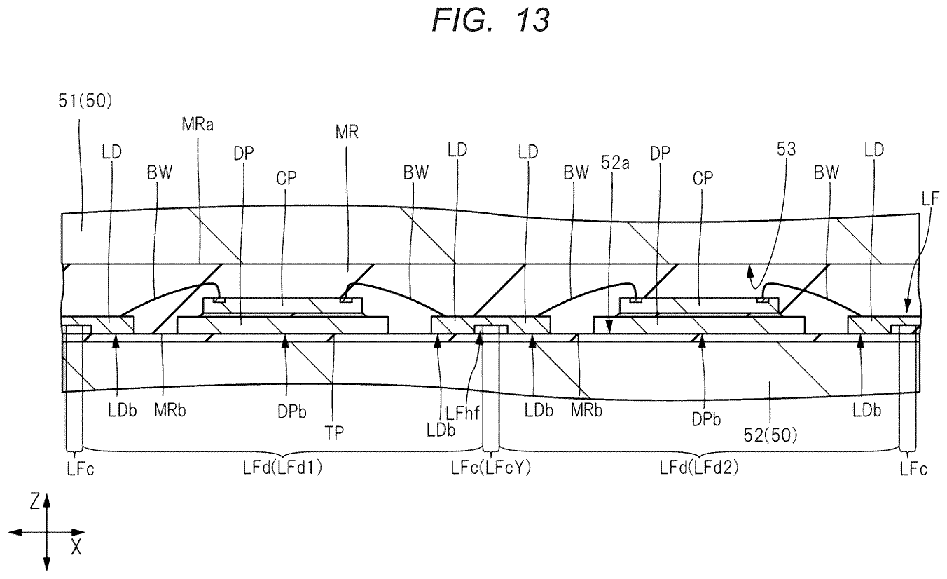

Next, in the sealing step shown in FIG. 7, as shown in FIG. 13, a sealing body MR that seals a part of the die pad DP, a part of each of the multiple leads LD, the multiple wires BW, and the semiconductor chip CP is formed. FIG. 12 is a plan view showing the sealing body formed in the sealing step shown in FIG. 7. FIG. 13 is an enlarged cross-sectional view showing the state in which the lead frame is placed in the cavity of the molding die along the line E-E of FIG. 12.

In this process, as shown in FIG. 13, the sealing body MR is formed so that the lower surfaces LDb of the multiple leads LD provided in each of the multiple devices forming sections LFd and the lower surface DPb of the die pad DP are exposed.

In this process, for example, the sealing body MR shown in FIG. 12 is formed by a so-called transfer mold method, which involves clamping the lead frame LF in the molding die 50 shown in FIG. 13, injecting softened resin into the molding die 50, and then curing it. The resin is made of insulating material.

The molding die 50 comprises an upper die (mold) 51 arranged on the lead frame LF and a lower die (mold) 52 arranged under the lead frame LF. The upper die 51 includes a clamping surface (not shown) for pressing the lead frame LF and a cavity (recess) 53 formed inside the clamping surface. Furthermore, the lower die 52 includes a support surface (mold surface, pressing surface, surface) 52a arranged so as to face the cavity 53 and support the lead frame LF. In the present embodiment, since a QFN type package is manufactured, the support surface 52a of the lower die 52 does not have a cavity formed therein.

In the sealing step, a sealing resin is pressed into the cavity 53 to seal the semiconductor chip CP (refer to FIG. 13) and multiple wires BW (refer to FIG. 13). A part of each of the multiple leads LD (excluding the lower surface LDb) and a part of the die pad DP (excluding the lower surface DPb) are also sealed with the sealing resin.

Furthermore, as shown in FIG. 13, a tape material (resin film) TP is arranged between the lead frame LF and the lower die 52. On the lower side (back side, mounting side) of the lead frame LF, a pressing force from the support surface 52a of the lower die 52 is applied through the tape material TP. Therefore, as shown in FIG. 13, the lower surface LDb of the lead LD and the lower surface DPb of the die pad DP are likely to adhere to the tape material TP. In other words, in the sealing step of the present embodiment, the sealing body MR is formed with the tape material adhering to the lower surface DPb of the die pad DP and the lower surface LDb of each of the multiple leads LD. By adhering the tape material TP, it is possible to prevent the sealing resin from wrapping around the lower surface LDb of the lead LD and the lower surface DPb of the die pad DP. In other words, the lower surface LDb of the lead LD and the lower surface DPb of the die pad DP can be exposed.

Next, the sealing body MR shown in FIG. 12 is formed by thermally curing the resin supplied into the cavity 53. Specifically, after the sealing body MR is molded by the cavity 53, a part of the thermosetting resin contained in the sealing body MR is heated until it hardens (referred to as provisional curing). Once it becomes possible to remove the lead frame LF from the molding die due to this provisional curing, the lead frame LF is removed from the molding die. Then, it is transported to a heating furnace for further heat treatment (cure bake). As a result, the remaining part of the thermosetting resin hardens, and the sealing body MR is obtained.

In the present embodiment, the sealing body MR is formed to collectively seal multiple devices forming sections LFd. Focusing on the part illustrated in FIG. 13, the sealing step includes the following steps. The sealing step includes a step of adhering a single piece of tape material TP across the device forming sections LFd1 and LFd2. Furthermore, the sealing step includes a step of accommodating both devices forming sections LFd1 and LFd2 in a cavity (single cavity) 53. Moreover, the sealing step includes a step of supplying resin into the cavity 53 and collectively sealing both devices forming sections LFd1 and LFd2.

It should be noted that there are cases such as the following for the timing of adhering the tape material TP to the lead frame LF. For example, in the case where an adhesive layer is provided on one surface of the tape material TP, there may be a case where the tape material TP is pre-attached before placing the lead frame LF in the cavity 53. Alternatively, for example, there is a method where the tape material TP is pre-placed on the support surface 52a of the lower mold 52, and the lead frame LF is placed thereon. In this case, the lead frame LF and the tape material TP are pressed and adhered to each other by the supply pressure of the sealing resin.

As in the present embodiment, a semiconductor package that forms a sealing body MR so as to collectively cover a plurality of device forming sections LFd arranged in an array (array) is called a MAP (Multi Array Package) type semiconductor device. Also, the sealing method that collectively seals a plurality of device forming sections LFd is called a Block Molding method. Since the MAP type semiconductor device can reduce the distance between each of the plurality of device forming sections LFd, the effective area on a single lead frame LF increases. That is, the number of products that can be obtained from a single lead frame LF increases. Thus, by increasing the effective area on a single lead frame LF, the manufacturing process can be made more efficient. Especially, in cases where dozens of products are obtained from a single lead frame LF, the effect of improved manufacturing efficiency due to the increased effective area is significant.

Here, in this process, as shown in FIG. 13, the sealing resin adheres by wrapping around in areas not adhered to the molding die 50 or the tape material TP. Therefore, a sealing body MR is formed on the thin-walled part LFhf formed by the half-etching process. In other words, in this process, the thin-walled part LFhf is sealed by the resin. Therefore, to expose the lower surface LDb2 of the part LDe shown in FIG. 3 from the sealing body MR, a process to remove the sealing body MR covering the lower surface LDb2 is necessary. In the present embodiment, a laser irradiating step shown in FIG. 7 is performed as the process to remove the sealing body MR covering the lower surface LDb2.

### <Laser Irradiating Step>

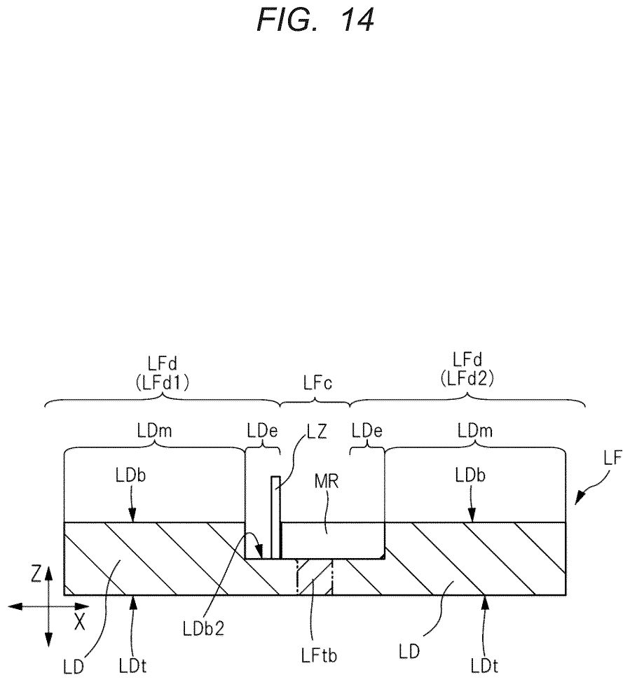

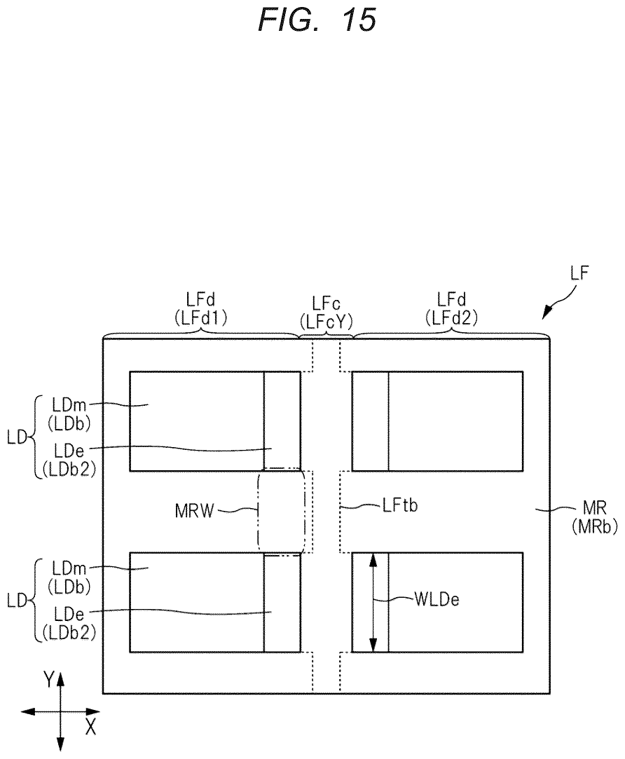

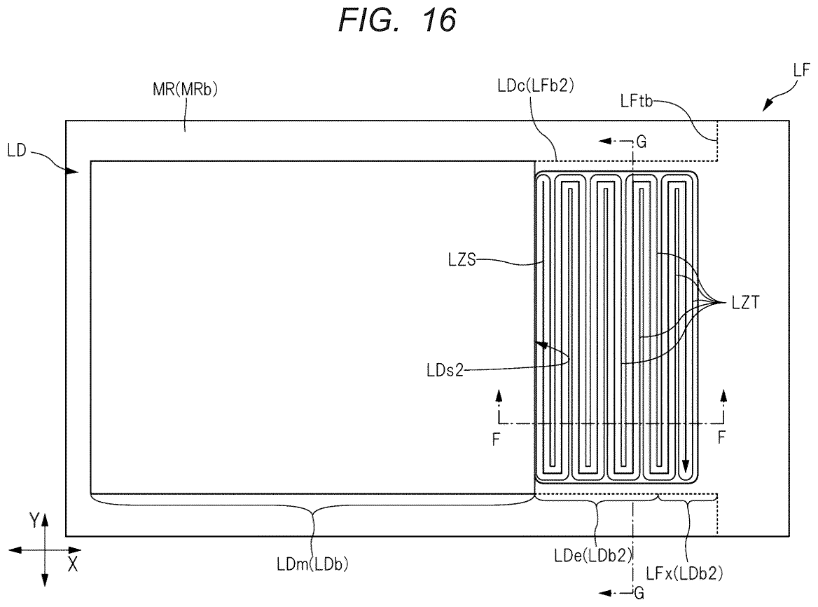

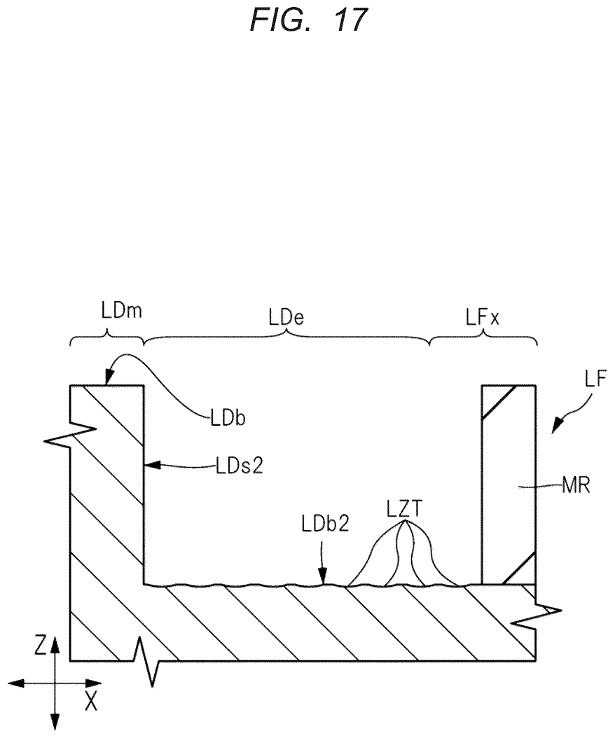

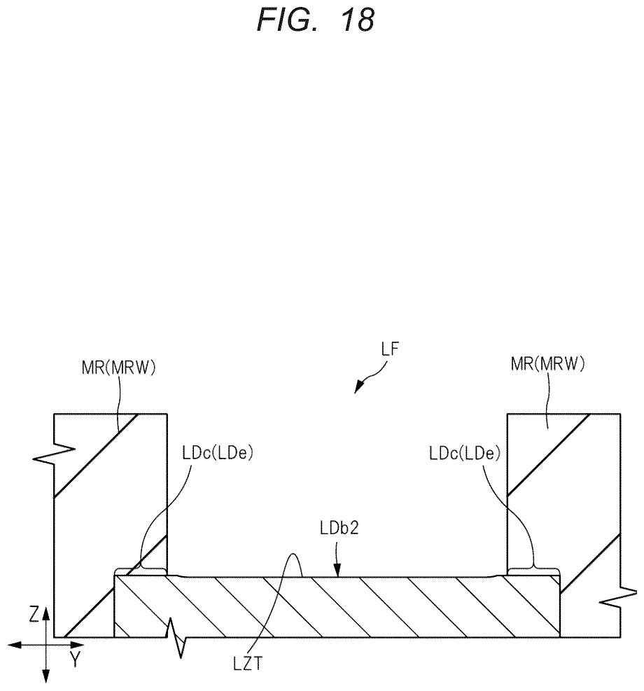

In the laser irradiating step shown in FIG. 7, after removing the tape material TP shown in FIG. 13, laser light is irradiated on the area covering parts of the multiple leads LD within the sealing body MR. FIG. 14 is an enlarged cross-sectional view showing the state of irradiating laser light on the sealing body covering the end parts of the leads in the laser irradiating step shown in FIG. 7. FIG. 15 is an enlarged plan view showing an example of the scanning direction of the position where the laser light is irradiated in the laser irradiating step shown in FIG. 7. FIG. 16 is an enlarged plan view showing an example after the sealing body has been removed by the laser irradiating step shown in FIG. 7. FIG. 17 is an enlarged cross-sectional view along the line F-F of FIG. 16. FIG. 18 is an enlarged cross-sectional view along the line G-G of FIG. 16.

As shown in FIG. 14, in the laser irradiating step, the lower surface LDb2 is exposed from the sealing body MR by selectively irradiating the part (region), which is covering the lower surfaces LDb2 of each of the plurality of leads LD, of the sealing body MR with a laser light LZ.

Focusing on the device forming section LFd1 shown in FIG. 15, a plurality of leads LD are arranged adjacent to each other in the Y direction so as to be spaced apart from each other. Among the sealing body MR, a part (region) covering the lower surface LDb2 of each of the plurality of leads LD is selectively removed. Therefore, the portion MRW described using FIG. 5 is formed between the parts LDe adjacent to each other in the Y direction (in other words, between the lower surfaces LDb2 adjacent to each other in the Y direction). In the laser irradiating step, the laser light LZ (refer to FIG. 14) is not irradiated on the portion MRW.

The phrase “selectively irradiating laser light on B among A” means that “laser light is irradiated on at least B, and there are parts on A where laser light is not irradiated.” Therefore, “selectively irradiating laser light on B among A” includes cases where there are parts within “B” that are not irradiated with laser light. Moreover, “selectively irradiating laser light on B among A” includes cases where a part of “A” is irradiated with the laser.

As a method for selectively removing the part covering the lower surface LDb2 of each of the plurality of leads LD after the sealing step, the method using laser irradiation is particularly effective. This is because the directivity of the laser light LZ can be enhanced. For example, in the present embodiment, the laser light LZ is an ultraviolet laser with a wavelength of 355 nm. The maximum output of the laser light LZ is 20 W (100 kHz). Also, the spot diameter of the laser light LZ (the diameter of the spot irradiated in a circular shape) is about 30 μm to 35 μm.

On the other hand, the width WLDe of the lower surface LDb2 (the length in the Y direction in the example shown in FIG. 15) is about 250 μm. That is, the irradiation area of the laser light LZ in the laser irradiating step of the present embodiment (the area of the irradiation range when the irradiation position of the laser light LZ is fixed) is smaller than the planar area of the lower surface LDb2.

Therefore, in order to expose most of the lower surface LDb2, it is necessary to scan the laser light LZ and sequentially remove the sealing body MR covering the lower surface LDb2. In the case of the present embodiment, for example, as schematically shown with arrows in FIG. 16, the irradiation position of the laser light LZ (refer to FIG. 14) is sequentially moved along the scanning trajectory LZS.

Moreover, from the perspective of improving the connection reliability between the bonding material SD1 shown in FIG. 6 and the lower surface LDb2 of the lead LD, it is necessary to reliably expose the lower surface LDb2. Therefore, in the laser irradiating step, the laser light LZ (refer to FIG. 14) is irradiated not only on the sealing body MR but also on the lower surface LDb2 of the part LDe of the lead LD.

Therefore, in the laser irradiating step, a plurality of grooves LZT extending in the Y direction are formed on the lower surface LDb2. Moreover, from the perspective of surface flatness, the following state is achieved: That is, as shown in FIG. 17, after the laser irradiating step is completed, the lower surface LDb2 is rougher than the lower surface LDb. In other words, after the laser irradiating step is completed, the flatness of the lower surface LDb2 is lower than that of the lower surface LDb.

In the case where the sealing body MR is removed by laser irradiation, the portion irradiated with the laser light LZ shown in FIG. 14 and the surrounding area thereof evaporate and are removed. Therefore, from the viewpoint of preventing parts other than the part covering the lower surface LDb2 of the sealing body MR from being removed, the range of the area to be irradiated with the laser light LZ in this process does not coincide with the range of the lower surface LDb2. Therefore, as shown in FIGS. 16 and 18, it is preferable that the sealing body MR remains without being removed at the peripheral part of the lower surface LDb2. In other words, after the laser irradiating step is completed, it is preferable that a part of the lower surface LDb2 (the part LDc shown in FIGS. 16 and 18) is covered with the sealing body MR. Furthermore, it is preferable that the part LDe of the lead LD includes the part LDc covered with the sealing body MR.

On the other hand, in the metal film forming step shown in FIG. 7, in order to form a metal film SD on the side surface LDs2 of the part LDm of the lead LD as shown in FIG. 3, it is necessary in this process to expose the side surface LDs2. Therefore, as shown in FIG. 16, the scanning trajectory LZS of the laser light LZ (refer to FIG. 14) exists near the side surface LDs2, and it is preferable that the groove LZT closest to the side surface LDs2 is in contact with the side surface LDs2. This allows the side surface LDs2 to be exposed from the sealing body MR during the laser irradiating step.

The structure of the multiple grooves LZT described above, or the structure having the part LDc covered by the sealing body MR in the part LDe, is a characteristic structure formed by removing a part of the sealing body MR by the laser irradiating step after the sealing process. Also, these structures remain in the completed semiconductor device PKG1 shown in FIG. 3. Therefore, regarding the completed semiconductor device PKG1, it is possible to determine whether the laser irradiating step of the present embodiment has been performed or not by the presence or absence of the grooves LZT shown in FIGS. 16 and 17, or by the presence or absence of the part LDc shown in FIGS. 16 and 18.

Moreover, in the part LDe of the lead LD shown in FIG. 3, the sealing body MR is not remaining at the tip farthest from the die pad DP (the boundary with the side surface LDs shown in FIG. 3). To ensure the removal of the sealing body MR in this part, in the case of the present embodiment, as shown in FIG. 16, the sealing body MR is removed in a wider range than the predetermined area of the part LDe of the lead LD.

Specifically, in the case of the present embodiment, the lead frame LF is arranged between the tie bar LFtb and the lead LD (specifically, the part LDe of the lead LD), and has a lead connection part LFx with a lower surface LDb2. After the laser irradiating step is completed, the lower surface LFb2 of the lead connection part LFx is partially exposed from the sealing body MR, and other parts are sealed by the sealing body.

Although not shown in the drawings, by controlling the output and irradiation time of the laser irradiation, it is possible to make the unevenness of the grooves LZT shown in FIGS. 16 and 17 small enough to be unrecognizable. Moreover, as a modified example for FIGS. 16 and 18, in the laser irradiating step, there are cases where the entire lower surface LDb2 is exposed (that is, all parts of the sealing body MR covering the lower surface LDb2 are removed).

Furthermore, the scanning trajectory LZS shown in FIG. 16 is an example, and there are various modified examples in the scanning direction of the laser light LZ (refer to FIG. 14). For instance, in the example shown in FIG. 16, multiple grooves LZT extend in the Y direction, but as a modified example, there are cases where multiple grooves LZT extend in the X direction. However, scanning the laser light LZ along the side surface LDs2 tends to prevent unevenness in the exposure state from the sealing body MR of the side surface LDs2. From this perspective, as shown in FIG. 16, it is preferable that multiple grooves LZT extend in the Y direction, which is the same direction as the extending direction of the side surface LDs2.

### Examined Example

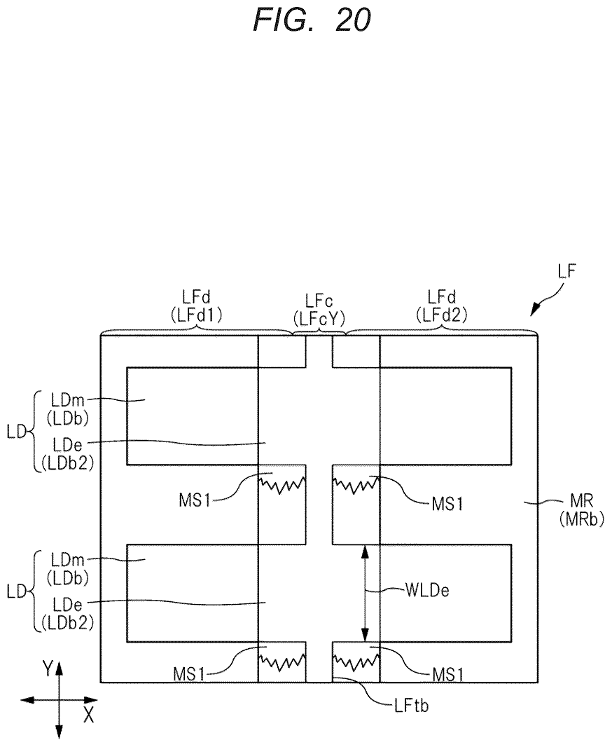

Meanwhile, as an examined example, the inventors of the present application have considered a method of exposing the lower surface LDb2 using a dicing blade instead of the laser irradiating step of the present embodiment. FIG. 19 is an enlarged cross-sectional view showing the examined example corresponding to FIG. 14. FIG. 20 is an enlarged plan view showing the examined example corresponding to FIG. 15.

The examined example shown in FIG. 19 differs from the manufacturing method of the semiconductor device of the present embodiment in that it includes a half-dicing step instead of the laser irradiating step shown in FIG. 7. In the half-dicing step, the sealing body MR embedded in the step portion ST (refer to FIG. 10) is removed by running a dicing blade (cutting edge) along the dicing part LFc (refer to FIG. 20).

The dicing blade DB1 is a ring-shaped or disc-shaped cutting tool, with multiple abrasive grains fixed to the cutting part located on the circumference of the circle. By pressing the cutting part of the dicing blade DB1, which has multiple abrasive grains fixed to it, against the workpiece, the workpiece can be cut and removed.

In the half-dicing step, the sealing body MR is machined by the dicing blade DB1, exposing the lower surface LDb2 of the part LDe of the lead LD. Furthermore, by running the dicing blade DB1 along the extending direction of the dicing part LFc (refer to FIG. 20), the lower surfaces LDb2 of multiple leads LD can be sequentially exposed.

In the case of this examined example, by rotating the dicing blade DB1 while running it linearly, continuous cutting processing can be performed on multiple leads LD. Therefore, compared to the laser irradiating step of the present embodiment, there is an advantage of higher manufacturing efficiency.

However, according to the study by the inventors of the present application, in the method of this examined example, there is a concern that neighboring leads LD may short-circuit due to the metal burr MS1 shown in FIG. 20 when the distance between neighboring leads LD is narrow.

The metal burr MS1 shown in FIG. 20 is formed by dragging the metal (copper, for example, in the case of the examined example) constituting the lead frame LF in the rotation direction of the dicing blade DB1 shown in FIG. 19 during the half-dicing process. In the example shown in FIG. 20, the metal burr MS1 is formed from the top to the bottom of the page.

Since the metal burr MS1 itself is made of copper or a copper alloy, for example, if the metal burr MS1 is oxidized by heat treatment, the wettability to solder significantly decreases. However, in order to improve the wettability of the lead LD to solder, as shown in FIG. 7, it is necessary to perform a metal film forming step that forms a metal film SD (see FIG. 3) made of a metal having higher wettability to solder than copper.

When the metal film forming step is performed in a state where the metal burr MS1 is exposed from the sealing body MR, a metal film SD (see FIG. 3) is also formed on the surface of the metal burr MS1. Therefore, as explained using FIG. 6, when mounting the semiconductor device of the examined example on the mounting substrate MB, solder wets and spreads not only on the exposed surface of the lead LD from the sealing body MR but also on the metal burr MS1.

Moreover, as shown in FIG. 20, in the case of the semiconductor device of the examined example, a cutting process is also performed on the portion (part) between the parts LDe of the adjacent leads LD the dicing blade DB1 (see FIG. 19). Therefore, the portion MRW shown in FIG. 15 does not exist.

In this case, the solder that has wetted and spread on the metal burr MS1 is likely to integrate with the solder spread on the adjacent lead LD. As a result, the adjacent leads LD are likely to be short-circuited through the solder.

In the case of the present embodiment, as shown in FIG. 7, the lower surface LDb2 shown in FIG. 15 is exposed by a laser irradiating step. Therefore, the metal burr MS1 shown in FIG. 20 does not occur. Hence, even after the metal film forming step following the laser irradiating step, the metal film SD (see FIG. 3) is formed on the lower surface LDb, lower surface LDb2, and side surface LDs2, but not between the adjacent leads LD.

Moreover, the portions MRW shown in FIGS. 5 and 15 function as an insulating material to ensure the insulation between the adjacent leads LD.

Therefore, according to the present embodiment, even when the spacing between the adjacent leads LD is narrow, it is possible to prevent short-circuiting between the adjacent leads LD. In other words, according to the present embodiment, since it is possible to prevent short-circuiting between the adjacent leads LD, the distance between the adjacent leads LD can be reduced. That is, it is possible to reduce the planar size of the semiconductor device.

### <Metal Film Forming Step>

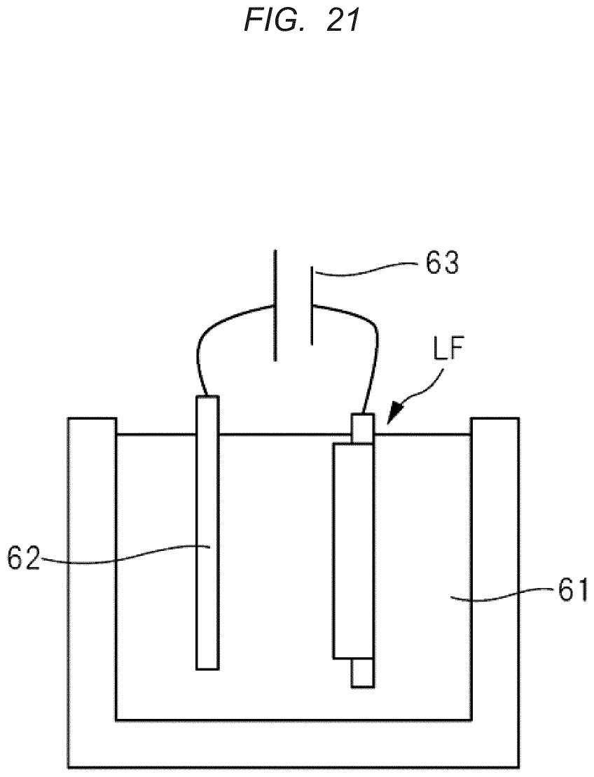

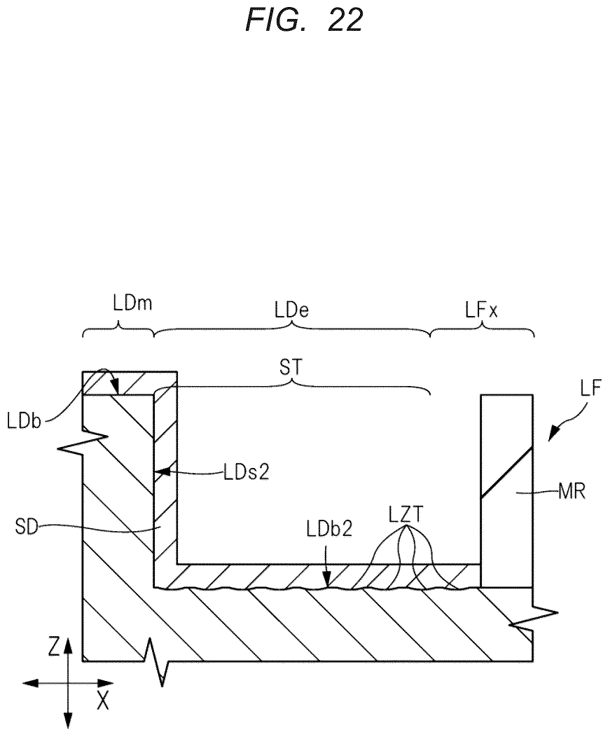

Next, in the solder film forming step shown in FIG. 7, after the laser irradiating step, a metal film SD is formed on the lower surface LDb and lower surface LDb2 shown in FIG. 22. FIG. 21 is an explanatory diagram schematically showing an example of the metal film forming step shown in FIG. 7. FIG. 22 is an enlarged cross-sectional view showing the state where the metal film is formed on the lead shown in FIG. 17.

In this process, for example, as shown in FIG. 21, the lead frame LF is immersed in a plating solution 61. The plating solution 61 is, for example, a solder solution. An anode rod 62 is immersed in the plating solution 61. In the electroplating method, the anode rod 62 is used as an anode, and the metal part of the lead frame LF is used as a cathode. Therefore, as illustrated in FIG. 21, the lead frame LF is connected to the negative pole of the power source 63, and the anode rod 62 is connected to the positive pole of the power source 63. When current is passed in this state, a reduction reaction occurs on the cathode side, and a metal film SD (see FIG. 22) is formed on the surface of the metal part exposed from the sealing body MR of the lead frame LF. This method is called the electroplating method (also known as electrolytic plating).

As shown in FIG. 22, by the electroplating method, a metal film SD is formed on the lower surface LDb, side surface LDs2, and lower surface LDb2 of the lead LD. This metal film SD is made of a metal material that has higher wettability to solder compared to copper or copper alloy, which is the base material of the lead frame LF. In the case of the present embodiment, as described above, the metal film SD is made of solder.

As already mentioned, in the case of the present embodiment, the sealing body MR embedded in the step portion ST shown in FIG. 10 (see FIG. 14) is removed by irradiating laser light LZ (see FIG. 14), therefore, the metal burr MS1 shown in FIG. 20 is not formed. For this reason, in the metal film forming step, the metal film SD is not formed between leads LD that are adjacent to each other within a single device forming part LFd (see FIG. 9).

As explained at the end of the lead frame preparation process, as a modified example for the present embodiment, when forming part LDe by half dicing, metal burrs may occur around part LDe. However, even if metal burrs are generated during the lead frame preparation process, they are sealed in the sealing process shown in FIG. 7. Therefore, even if part LDe is formed by half dicing during the lead frame preparation process, the metal film SD is not formed on the metal burrs in the metal film forming step.

As a modified example for the present embodiment, there is a case where the metal film SD (see FIG. 22) is formed by the electroless plating method. In the case of the electroplating method described as the present embodiment, it is necessary to pass a current through the member (plating target member) on which the plating film is formed, so it needs to be performed before the dicing process described later. However, the film quality of the metal film SD is preferable when formed by electroplating rather than by forming through electroless plating.

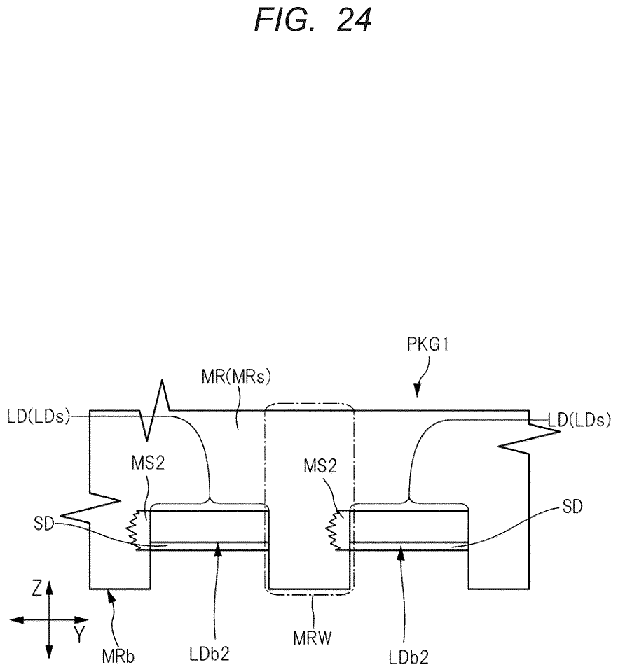

On the other hand, in the case of the electroless plating method, since it is not necessary to pass a current through the plating target member, it is conceivable to perform the metal film forming step after the singulation step described later. However, if electroless plating is performed after the dicing process, a plating film is also formed on the surface of the metal burr MS2 (see FIG. 24 described later). In this case, there is a concern that adjacent leads LD may be short-circuited through the metal burr MS2. Therefore, even when using electroless plating, it is preferable to perform the metal film forming step before the dicing process.

### <Singulation Step>

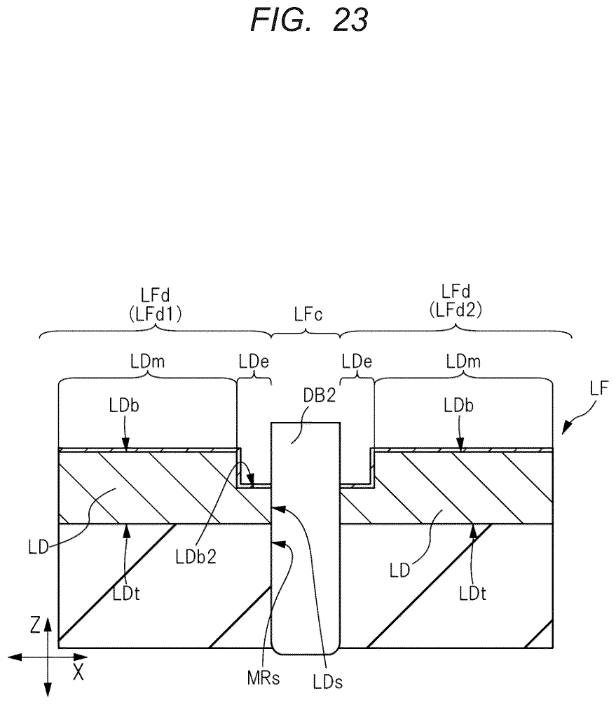

Next, in the dicing process shown in FIG. 7, by running the dicing blade DB2 shown in FIG. 23 along the dicing part LFc shown in FIG. 8, each of the multiple devices forming parts LFd is divided and diced. This process also includes the step of separating the device forming part LFd1 and the device forming part LFd2 shown in FIG. 23. FIG. 23 is an enlarged cross-sectional view showing the dicing process shown in FIG. 7. Note that FIG. 23 corresponds to the enlarged cross-section shown in FIG. 14. FIG. 24 is an enlarged side view showing one side of the semiconductor device after the dicing process shown in FIG. 7 is completed.

The dicing blade DB2 is a ring-shaped or disc-shaped cutting tool, with multiple abrasive grains fixed to the cutting part located on the circumference of the circle. By pressing the cutting part of the dicing blade DB2, which has multiple abrasive grains fixed to it, against the workpiece, the workpiece can be cut and removed.

In the case of the present embodiment, among the sealing body MR shown in FIG. 15, the portion sealing the tie bar LFtb of the dicing part LFc is cut together with the tie bar LFtb. Also, the lead connection part LFx shown in FIG. 16 is cut in this process.

As shown in FIG. 23, by this process, the side surface LDs of the lead LD and the side surface MRs of the sealing body MR are formed. In the case of the present embodiment, since the lead LD and the sealing body MR are machined together, as already explained using FIG. 3, the side surface LDs is positioned on the extension of the side surface MRs of the sealing body MR.

However, in this process, since the machining is performed using the dicing blade DB2, as explained as an examined example, metal burrs MS2 (refer to FIG. 24) may occur. As shown in FIG. 24, the metal burrs MS2 are formed on the side surface of the semiconductor device PKG1.

However, most of the metal burrs MS2 consist of copper or a copper alloy, which is the base material of the lead frame LF (refer to FIG. 23). The component of the metal film SD contained in the metal burrs MS2 is minimal. Also, in the case of the present embodiment, since the singulation step is performed after the metal film forming step, even if the metal burrs MS2 occur, a metal film with high wettability to solder is not formed on the metal burrs MS2.

Therefore, if the metal burrs MS2 are oxidized, for example, by heat treatment, the wettability of the metal burrs MS2 to solder is very low. Thus, even if the metal burrs MS2 occur, the possibility of the adjacent leads LD short-circuiting through the metal burrs MS2 is low.

Through the above processes, the semiconductor device PKG1 shown in FIGS. 1 to 5 is obtained. Thereafter, tests such as electrical testing and appearance inspection are conducted as necessary, and those judged as non-defective are transported to the next process, such as the packaging process of the semiconductor device.

### First Modified Example

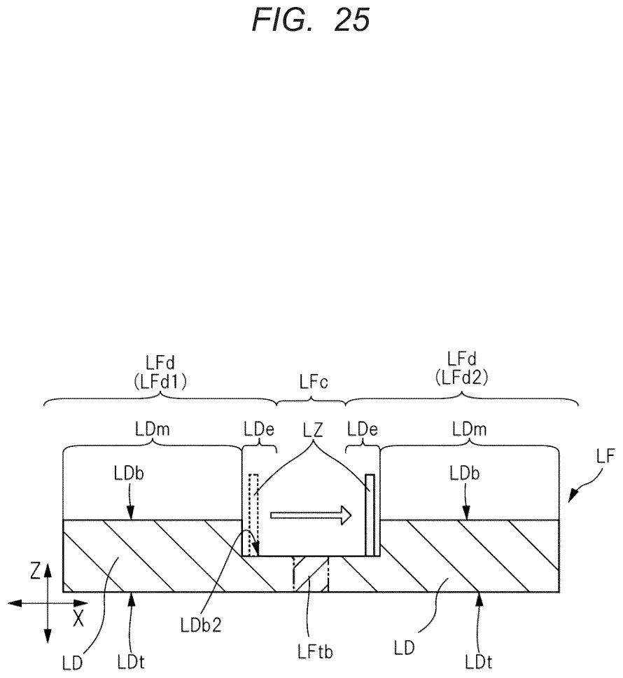

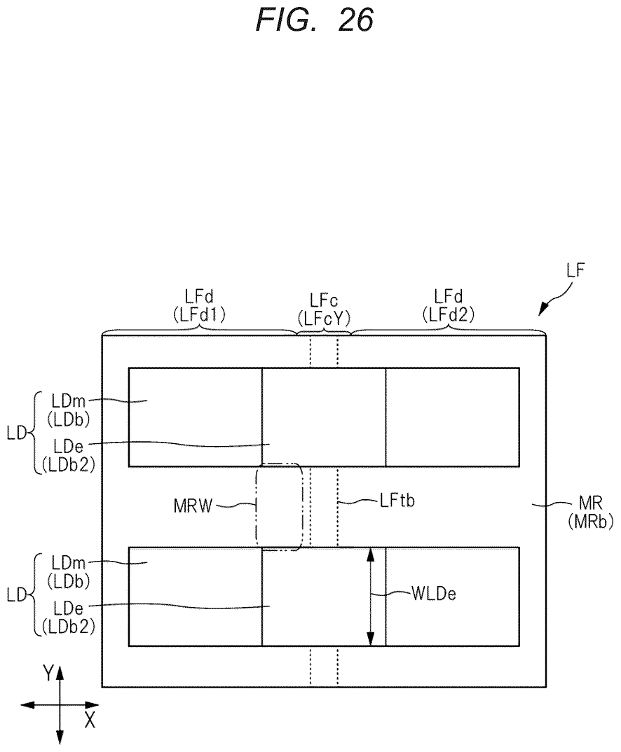

Next, a modified example of the embodiment described above will be explained. FIG. 25 is an enlarged cross-sectional view showing a modified example for FIG. 14. FIG. 26 is an enlarged plan view showing a modified example for FIG. 15. In the described embodiment, during the laser irradiating step, the laser light LZ (refer to FIG. 14) is not irradiated on the tie bar LFtb, and it was explained that the lower surface LDb2 of the tie bar LFtb remains covered by the sealing body MR upon completion of the laser irradiating step.

On the other hand, in the case of this modified example, during the laser irradiating step, as shown in FIG. 25, the laser light LZ is moved to expose not only the lower surface LDb2 of the part LDe of the lead LD but also a part of the lower surface LDb2 of the tie bar LFtb from the sealing body MR (refer to FIG. 26).

In the case of this modified example, it is possible to perform laser irradiation collectively on two adjacent leads LD in the X direction. Therefore, when performing laser irradiation on a large number of leads LD, it is possible to halve the number of times the laser light LZ is turned off. Thus, as shown in FIGS. 14 and 15, it is possible to improve the processing efficiency of the laser irradiating step compared to the method of irradiating with laser light LZ (see FIG. 14) so as to leave the sealing body MR on the tie bar LFtb.

However, from the viewpoint of suppressing the occurrence of metal burrs that are likely to occur in the dicing process, it is preferable to perform dicing with the metal member sealed in the sealing body MR. Therefore, from the viewpoint of suppressing the occurrence of metal burrs, as shown in FIG. 15, it is preferable that the entire tie bar LFtb remains sealed in the sealing body MR at the stage where the laser irradiating step is completed.

### Second Modified Example

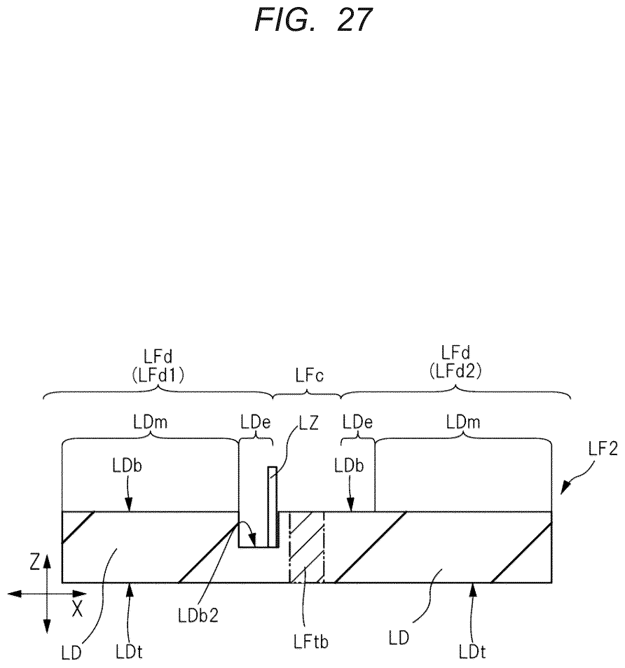

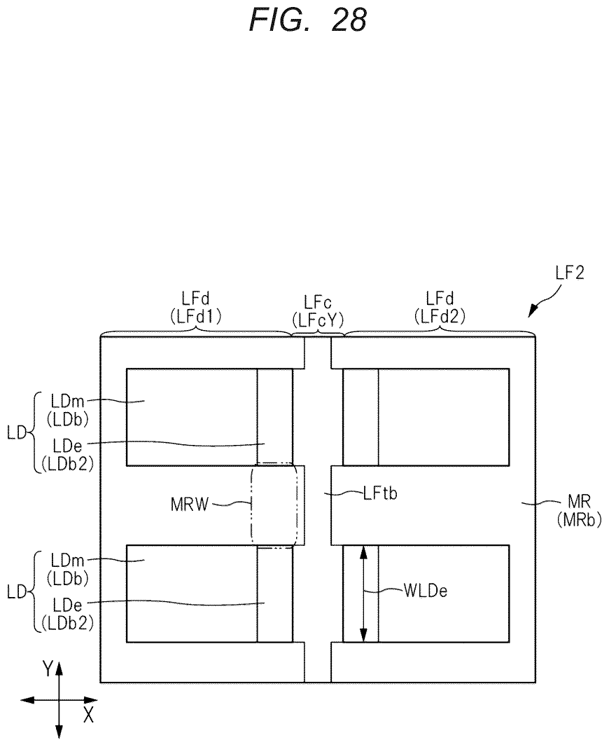

Next, another modified example for the above-described embodiment will be explained. As briefly explained in the section of the lead frame preparation process, as a modified example for the above embodiment, in the lead frame preparation process, there is no step formed, and in the laser irradiating step shown in FIG. 7, by removing the metal of the lead LD (refer to FIG. 27), a method of forming the part LDe shown in FIGS. 3 and 5 exists. FIG. 27 is an enlarged cross-sectional view showing another modified example for FIG. 14. FIG. 28 is an enlarged plan view showing another modified example for FIG. 15.

The lead frame LF2 shown in FIGS. 27 and 28 differs from the lead frame LF shown in FIGS. 10 and 11 in that the thin part LFhf (in other words, the step part ST shown in FIG. 10) shown in the lead frame preparation process in FIG. 7 is not formed. In the case of this second modified example, it differs from the embodiment explained using FIGS. 14 and 15 in that, in the laser irradiating step shown in FIGS. 27 and 28, the part LDe shown in FIGS. 3 and 5 is formed by irradiating a part of the lower surface LDb of the lead LD with a laser light LZ (refer to FIG. 27), thereby removing the metal (copper or copper alloy) composing the lead frame LF2.

In the case of this second modified example, it is possible to omit the process of forming the thin part LFhf shown in FIGS. 10 and 11 in the lead frame preparation process.

However, in the laser irradiating step, when removing the metal, compared to removing the sealing body MR (refer to FIG. 28) mainly made of resin, the irradiation time of the laser light LZ (refer to FIG. 27) becomes longer. Therefore, from the viewpoint of improving the overall manufacturing efficiency, the method explained using FIGS. 14 and 15 is preferable.

Regarding the manufacturing method of the semiconductor device, which is this second modified example, when extracting the technical idea, it can be expressed as follows.

Namely, a method of manufacturing a semiconductor device according to this modified example comprises: (a) preparing a lead frame including: a die pad having a first upper surface and a first lower surface opposite the first upper surface, and a plurality of leads spaced apart from the die pad, wherein each of the plurality of leads has a second upper surface facing in the same direction as the first upper surface and a second lower surface opposite the second upper surface; (b) mounting a semiconductor chip on the first upper surface of the die pad, wherein the semiconductor chip has a plurality of electrodes; (c) electrically connecting the plurality of electrodes of the semiconductor chip with the plurality of leads via a plurality of conductive members, respectively; (d) sealing a part of the die pad, a first part of each of the plurality of leads, the plurality of conductive members and the semiconductor chip with a resin made of an insulating material in a state that a tape material is in contact with the first lower surface of the die pad and the second lower surface of each of the plurality of leads, and forming a sealing body having a third upper surface facing in the same direction as the first upper surface and a third lower surface opposite the third upper surface; (e) after removing the tape material, irradiating a part of the second lower surface of each of the plurality of leads with a laser light; and (f) after the (e), forming a metal film on the second lower surface of each of the plurality of leads and on a portion, which is exposed by irradiating the laser light, of each of the plurality of leads, wherein each of the plurality of leads of the lead frame after completing a step of the (e) includes: a first portion having the second upper surface and the second lower surface; and a second portion located further away from the die pad than the first portion and having a thickness which is smaller than the first portion, wherein the plurality of leads prepared in the (a) is arranged in a first direction, wherein the second portion includes: a second upper surface and a fourth lower surface opposite the second upper surface, wherein a length from the second upper surface to the fourth lower surface is less than a length from the second upper surface to the second lower surface, and wherein in the step (e), the fourth lower surface is formed by selectively irradiating the part of each of the plurality of leads with the laser light.

### Other Modified Examples

In addition to the modified example described above, the described technology can be applied to various modified examples. For instance, in the embodiment and modified example described, an explanation was given for a QFN type semiconductor device, where multiple leads are arranged on each of the four sides of the semiconductor device as an example. However, the arrangement of the multiple leads is not limited to the QFN type. For example, it can be applied to a DEN type semiconductor device, where multiple leads LD are arranged only on two sides that are opposite each other among the four sides of the semiconductor device.

As described above, although the invention made by the present inventor has been specifically described based on the embodiment, the present invention is not limited to the above embodiment, and it is needless to say that various modifications can be made without departing from the gist thereof.

What is claimed is:

1. A method of manufacturing a semiconductor device, comprising:
(a) preparing a lead frame including:
a die pad having a first upper surface and a first lower surface opposite the first upper surface, and
a plurality of leads spaced apart from the die pad, wherein each of the plurality of leads has a second upper surface facing in the same direction as the first upper surface and a second lower surface opposite the second upper surface;
(b) mounting a semiconductor chip on the first upper surface of the die pad, wherein the semiconductor chip has a plurality of electrodes;
(c) electrically connecting the plurality of electrodes of the semiconductor chip with the plurality of leads via a plurality of conductive members, respectively;
(d) sealing a part of the die pad, a first part of each of the plurality of leads, the plurality of conductive members and the semiconductor chip with a resin made of an insulating material in a state that a tape material is in contact with the first lower surface of the die pad and the second lower surface of each of the plurality of leads, and forming a sealing body having a third upper surface facing in the same direction as the first upper surface and a third lower surface opposite the third upper surface;
(e) removing the tape material, and irradiating a region of the sealing body with a laser light, wherein the region covers a second part of each of the plurality of leads;
(f) after the (e), forming a metal film on the second lower surface of each of the plurality of leads and on the second part of each of the plurality of leads,
wherein each of the plurality of leads of the lead frame prepared in the (a) includes:
a first portion having the second upper surface and the second lower surface; and
a second portion located further away from the die pad than the first portion and having a thickness which is smaller than a thickness of the first portion,
wherein the plurality of leads of the lead frame prepared in the (a) is arranged in a first direction,
wherein the second portion includes:
the second upper surface; and
a fourth lower surface opposite the second upper surface,
wherein a length from the second upper surface to the fourth lower surface is less than a length from the second upper surface to the second lower surface, and
wherein in the (e), the fourth lower surface of the second portion of each of the plurality of leads is exposed from the sealing body by selectively irradiating the region of the sealing body.

2. The method according to claim 1,
wherein the lead frame prepared in the (a) includes:
a first device forming portion;
a second device forming portion arranged next to the first device forming portion in a second direction which is crossing the first direction; and
a dicing portion extending in the first direction and located between the first device forming portion and the second device forming portion, and
wherein the step (d) includes:
(d1) adhering a single piece of the tape material across the first device forming portion and the second device forming portion;
(d2) housing the first device forming portion and the second device forming portion in a cavity; and
(d3) supplying the resin into the cavity, and collectively sealing each of the first device forming portion and the second device forming portion.

3. The method according to claim 2, further comprising:
(g) after the (f), separating the first device forming portion and the second device forming portion by running a dicing blade, which is a rotating blade, along the dicing portion,
wherein each of the first device forming portion and the second device forming portion includes the die pad and the plurality of leads, and
wherein the dicing portion includes a tie bar that is connected to each of the plurality of leads in the first device forming portion and the plurality of leads in the second device forming portion, and that is extending in the first direction.

4. The method according to claim 1, wherein the (a) includes a step of forming the second portion by removing a portion of each of the plurality of leads with an etching process.

5. The method according to claim 1, wherein, in the (e), a plurality of grooves is formed on the fourth lower surface.

6. The method according to claim 1, wherein after the (e), the fourth lower surface is rougher than the second lower surface.

7. The method according to claim 1, wherein after the (e), a part of the fourth lower surface is covered with the sealing body.

8. The method according to claim 1, wherein an irradiation area of the laser light irradiated in the (e) is smaller than a planar area of the fourth lower surface.

9. The method according to claim 1,
wherein the plurality of leads arranged in the first direction includes two leads adjacent to each other,
wherein a part of the sealing body made of the insulating material is interposed between the second portion of an one of the two leads and the second portion of an other of the two leads, and
wherein, in a thickness direction of the sealing body, a length from the third upper surface to the third lower surface of the part of the sealing body is larger than a length from the third upper surface of the sealing body to the fourth lower surface of the second portion of each of the plurality of leads.

10. A semiconductor device comprising:
a die pad having a first upper surface and a first lower surface opposite the first upper surface;
a plurality of leads spaced apart from the die pad, wherein each of the plurality of leads has a second upper surface facing in the same direction as the first upper surface and a second lower surface opposite the second upper surface;
a semiconductor chip mounted on the first upper surface of the die pad, wherein the semiconductor chip has a plurality of electrodes;
a plurality of conductive members electrically connecting the plurality of electrodes of the semiconductor chip with the plurality of leads; and
a sealing body sealing a part of the die pad, a first part of each of the plurality of leads, the plurality of conductive members and the semiconductor chip such that the first lower surface of the die pad and the second lower surface of each of the plurality of leads are exposed from the third lower surface, wherein the sealing body has a third upper surface facing in the same direction as the first upper surface and the third lower surface opposite the third upper surface,
wherein each of the plurality of leads includes:
a first portion having the second upper surface and the second lower surface; and
a second portion located further away from the die pad than the first portion and having a thickness which is smaller than a thickness of the first portion,
wherein the plurality of leads is arranged in a first direction,
wherein the second portion includes:
the second upper surface; and
a fourth lower surface opposite the second upper surface,
wherein a length from the second upper surface to the fourth lower surface is less than a length from the second upper surface to the second lower surface,
wherein the plurality of leads arranged in the first direction includes two leads adjacent to each other,
wherein a part of the sealing body made of an insulating material is interposed between the second portion of an one of the two leads and the second portion of an other of the two leads, and
wherein, in a thickness direction of the sealing body, a length from the third upper surface to the third lower surface of the part of the sealing body is larger than a length from the third upper surface of the sealing body to the fourth lower surface of the second portion of each of the plurality of leads.

11. The semiconductor device according to claim 10, wherein a plurality of grooves is formed on the fourth lower surface.

12. The semiconductor device according to claim 10, wherein the fourth lower surface is rougher than the second lower surface.

13. The semiconductor device according to claim 10, wherein a part of the fourth lower surface is covered with the sealing body.

14. The semiconductor device according to claim 10,
wherein each of the plurality of leads has a plurality of lead side surfaces,
wherein the sealing body has a sealing body side surface intersecting with each of the third upper surface and the third lower surface, and
wherein a first lead side surface of the plurality of lead side surfaces, which is located at the farthest position from the die pad, and the sealing body side surface are arranged within the same plane with each other.
